(19) United States
(12) Patent Application Publication
(10) Pub. No.: US 2026/0114212 A1
(43) Pub. Date: Apr. 23, 2026

(54) CLEANING APPARATUS

(71) Applicant: Taiwan Semiconductor Manufacturing Company Limited, Hsin-Chu (TW)

(72) Inventors: I-Pin CHAN, Hsin-Chu County (TW); Shing Long LEE, Hsinchu City (TW)

(21) Appl. No.: 18/921,094

(22) Filed: Oct. 21, 2024

(51) Int. Cl. H01L 21/67; A46B 13/00; A46B 13/04; H01L 21/02

(52) U.S. Cl. CPC H10P 72/0412; A46B 13/001; A46B 13/04; H10P 70/27; A46B 2200/3073

(57) ABSTRACT

An apparatus is provided. The apparatus includes a wafer support assembly configured to support a semiconductor wafer in a cleaning position. The apparatus includes a wafer cleaning assembly configured to apply a fluid including hydrogen to the semiconductor wafer while the semiconductor wafer is in the cleaning position.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a perspective view of a cleaning apparatus, in accordance with some embodiments.

FIG. 1B illustrates a side view of a cleaning apparatus, in accordance with some embodiments.

FIG. 1C illustrates a side view of a cleaning apparatus, in accordance with some embodiments.

FIG. 2A illustrates a perspective view of a cleaning apparatus, in accordance with some embodiments.

FIG. 2B illustrates a side view of a cleaning apparatus, in accordance with some embodiments.

FIG. 3A illustrates a top view of a cleaning apparatus, in accordance with some embodiments.

FIG. 3B illustrates a side view of a cleaning apparatus, in accordance with some embodiments.

FIG. 3C illustrates a top view of a cleaning apparatus, in accordance with some embodiments.

FIG. 3D illustrates a side view of a cleaning apparatus, in accordance with some embodiments.

FIG. 4A illustrates a perspective view of a roller, in accordance with some embodiments.

FIG. 4B illustrates a top view of a roller, in accordance with some embodiments.

FIG. 5A illustrates a side view of a cleaning apparatus, in accordance with some embodiments.

FIG. 5B illustrates a side view of a cleaning apparatus, in accordance with some embodiments.

FIG. 5C illustrates a side view of a cleaning apparatus, in accordance with some embodiments.

FIG. 5D illustrates a side view of a cleaning apparatus, in accordance with some embodiments.

FIG. 6 illustrates a cleaning apparatus, in accordance with some embodiments.

FIG. 7 illustrates a diagram of a scenario associated with a cleaning apparatus, in accordance with some embodiments.

FIG. 8 illustrates a diagram of a cleaning fluid system, in accordance with some embodiments.

FIG. 9 illustrates a diagram of a cleaning apparatus, in accordance with some embodiments.

FIG. 10 is a flow diagram illustrating a method, in accordance with some embodiments.

FIG. 11 is a representation of a data structure, in accordance with some embodiments.

FIG. 12 is a flow diagram illustrating a method, in accordance with some embodiments.

FIG. 13 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

A cleaning apparatus is used to perform a cleaning process on a semiconductor wafer. During the cleaning process, the cleaning apparatus applies a cleaning fluid to the semiconductor wafer in conjunction with a brushing process performed using a set of brushes of the cleaning apparatus. In accordance with some embodiments, the cleaning fluid applied to the semiconductor wafer comprises hydrogen and is heated using a fluid temperature controller. In some embodiments, the residue comprises tungsten oxide residue. As compared to a cleaning apparatus that does not comprise such features, characteristics, etc., the cleaning process provides a cleaner semiconductor wafer with a reduced amount of residue remaining on the semiconductor wafer after the cleaning process, such as due, at least in part, to at least one of (i) the hydrogen inducing a reverse reaction of the tungsten oxide residue, or (ii) the fluid temperature controller increasing a temperature of the cleaning fluid to increase a speed of the reverse reaction.

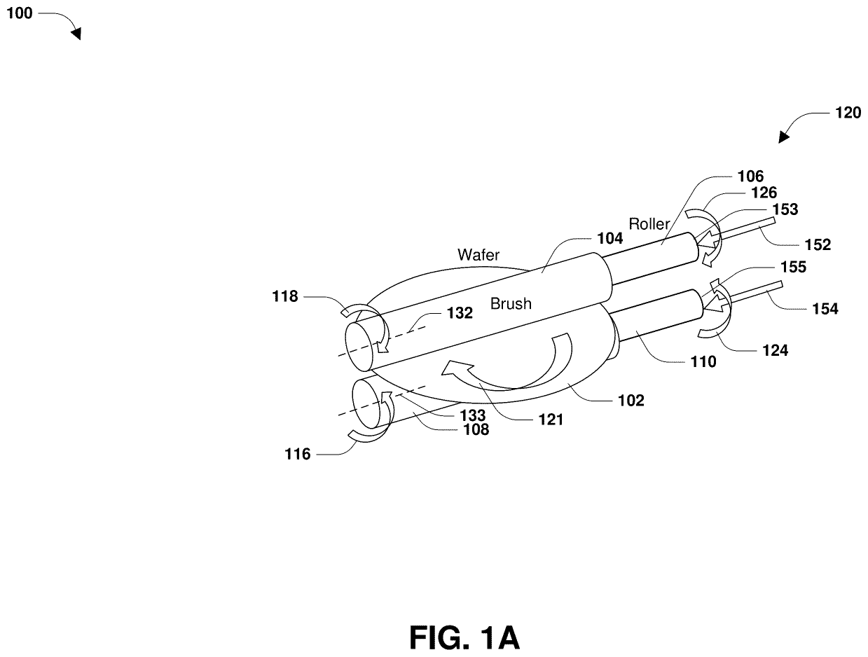

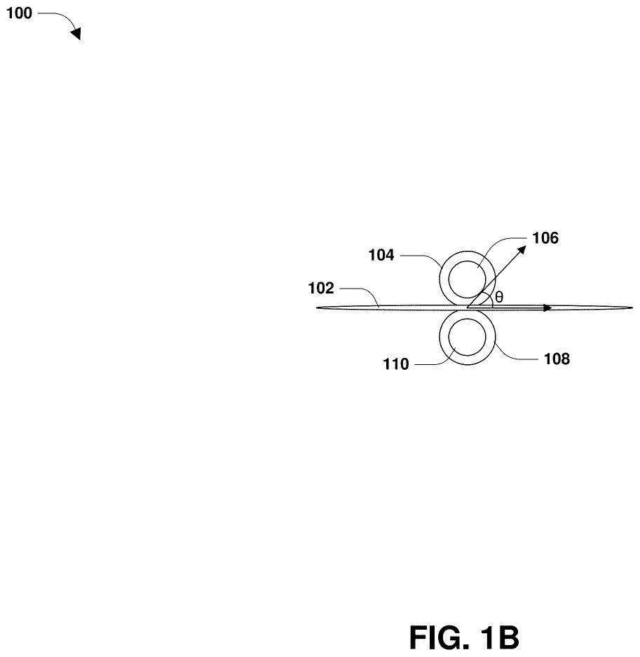

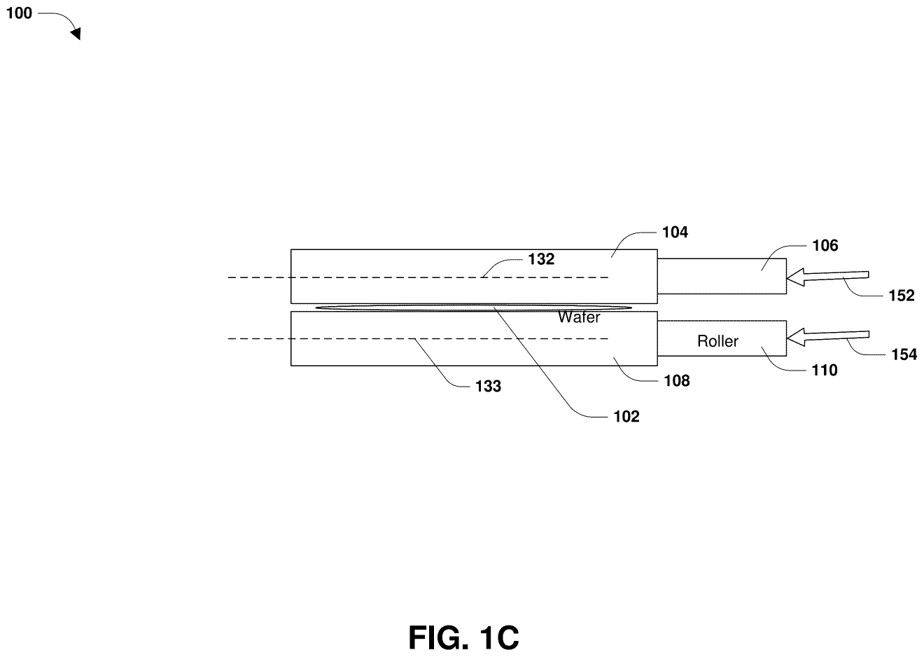

FIGS. 1A-1C illustrate a cleaning apparatus 100 according to some embodiments. FIG. 1A illustrates a perspective view of the cleaning apparatus 100, in accordance with some embodiments. In some embodiments, the cleaning apparatus 100 comprises a wafer cleaning assembly 120 configured to perform a cleaning process to clean a semiconductor wafer 102. In some embodiments, the cleaning process is performed to remove one or more contaminants (e.g., residue from a prior semiconductor fabrication process) from the semiconductor wafer 102. In some embodiments, the wafer cleaning assembly 120 comprises a set of brushes (e.g., a set of one or more brushes). In some embodiments, the cleaning process comprises a brushing process (e.g., a wafer scrubbing process) using the set of brushes. In some embodiments, the cleaning apparatus 100 performs the brushing process in conjunction with a cleaning fluid (e.g., a rinse). In some embodiments, the cleaning fluid is applied to the semiconductor wafer 102 during the cleaning process. In some embodiments, application of the cleaning fluid to the semiconductor wafer 102 in conjunction with the brushing process removes the one or more contaminants from the semiconductor wafer 102. Embodiments are contemplated in which the cleaning process comprises application of the cleaning fluid to the semiconductor wafer 102 to remove the one or more contaminants from the semiconductor wafer 102 without the brushing process.

In some embodiments, the set of brushes comprises at least one of a first brush 104 or a second brush 108. In some embodiments, the wafer cleaning assembly 120 comprises at least one of a first roller 106 coupled to the first brush 104 or a second roller 110 coupled to the second brush 108. In some embodiments, the first roller 106 comprises at least one of polyether ether ketone (PEEK), polyvinylidene fluoride (PVDF), or other suitable material. In some embodiments, the second roller 110 comprises at least one of PEEK, PVDF, or other suitable material.

In some embodiments, the cleaning process is performed while the semiconductor wafer 102 is in a cleaning position. FIG. 1A depicts the semiconductor wafer 102 in the cleaning position relative to the first brush 104 and the second brush 108 in accordance with some embodiments. In some embodiments, the semiconductor wafer 102 is between the first brush 104 and the second brush 108 when the semiconductor wafer 102 is in the cleaning position. In some embodiments, the first brush 104 at least partially surrounds the first roller 106. In some embodiments, the first brush 104 is configured to be rotated in a rotational direction 118 by the first roller 106. In some embodiments, the first roller 106 is rotated in a rotational direction 126 using a first driving mechanism (not shown), such as a motor configured to drive the first roller 106, to rotate the first brush 104 in the rotational direction 118 about a first axis of rotation 132. In some embodiments, the second brush 108 is configured to be rotated in a rotational direction 116 by the second roller 110. In some embodiments, the second roller 110 is rotated in a rotational direction 124 using a second driving mechanism (not shown), such as a motor configured to drive the second roller 110, to rotate the first brush 104 in the rotational direction 116 about a second axis of rotation 133. In some embodiments, the second axis of rotation 133 is about parallel to the first axis of rotation 132. Embodiments are contemplated in which the second axis of rotation 133 is not parallel to the first axis of rotation 132.

In some embodiments, during the cleaning process, at least one of (i) the first brush 104 is in contact with a first surface of the semiconductor wafer 102, (ii) the second brush 108 is in contact with a second surface of the semiconductor wafer 102 (e.g., the second surface is on an opposite side of the semiconductor wafer 102 as the first surface the cleaning apparatus 100), (iii) the semiconductor wafer 102 is rotated in a rotational direction 121, (iv) the first brush 104 is rotated in the rotational direction 118 (by the first roller 106, for example), or (v) the second brush 108 is rotated in the rotational direction 116 (by the second roller 110, for example).

In some embodiments, the wafer cleaning assembly 120 comprises a first set of outlets (e.g., a first set of one or more outlets) configured to emit a first cleaning fluid to at least one of the first brush 104 or the semiconductor wafer 102. In some embodiments, the first set of outlets are defined by the first roller 106. In some embodiments, the first set of outlets are defined by a portion, of the first roller 106, that is at least one of surrounded by or adjacent to the first brush 104. In some embodiments, the first roller 106 comprises a first roller inlet 153 configured to receive the first cleaning fluid. In some embodiments, a conduit 152 is used to conduct the first cleaning fluid to and/or through the first roller inlet 153 into the first roller 106. In some embodiments, the first roller 106 defines a conduit through which the first cleaning fluid travels from the first roller inlet 153 to the first set of outlets to be emitted through the first set of outlets.

In some embodiments, during (and/or prior to) the cleaning process, the first cleaning fluid is dispensed from the first set of outlets to at least one of the first brush 104 or the first surface of the semiconductor wafer 102. In some embodiments, the first brush 104 is soaked with at least some of the first cleaning fluid that was emitted by the first set of outlets. In some embodiments, during the brushing process, at least some of the first cleaning fluid is transferred from the first brush 104 to the first surface of the semiconductor wafer 102 while at least one of (i) the first brush 104 is in contact with the first surface of the semiconductor wafer 102, (ii) the first brush 104 is rotated in the rotational direction 118, or (iii) the semiconductor wafer 102 is rotated in the rotational direction 121. In some embodiments, the brushing process removes one or more contaminants (e.g., residue from a prior semiconductor fabrication process) from the semiconductor wafer 102, such as due, at least in part, to (i) mechanical action of the first brush 104 on the semiconductor wafer 102 and/or contaminants on the semiconductor wafer 102 (e.g., the mechanical action dislodges the contaminants), (ii) a first reverse reaction of an oxidized metal caused by application of the first cleaning fluid to the semiconductor wafer 102, or (iii) washing away of dislodged contaminants by the first cleaning fluid. In some embodiments, the mechanical action depends upon at least one of (i) a type of the first brush 104, (ii) a material of the first brush 104, or (iii) an amount of the first cleaning fluid applied to the semiconductor wafer 102. In some embodiments, the first brush 104 comprises at least one of a Polyvinyl Alcohol (PVA) brush, a nylon brush, a polyurethane brush, a polyester brush, a polytetrafluoroethylene (PTFE) brush, or other type of brush. In some embodiments, at least some of the first cleaning fluid dispensed during the cleaning process is emitted from the first set of outlets towards the semiconductor wafer 102 (e.g., at least some of the first cleaning fluid is dispensed directly onto the first surface of the semiconductor wafer 102 from the first set of outlets).

In some embodiments, the first reverse reaction comprises a reduction-oxidation (redox) reaction. In some embodiments, the first cleaning fluid comprises water (e.g., de-ionized water). In some embodiments, the first reverse reaction comprises a reaction (e.g., a redox reaction) between water (e.g., de-ionized water) of the first cleaning fluid and metal oxide (e.g., oxidized metal residue from a prior semiconductor fabrication process) on the semiconductor wafer 102. In some embodiments, the first reverse reaction comprises a reaction (e.g., a redox reaction) between water (e.g., de-ionized water) of the first cleaning fluid and tungsten oxide (e.g., tungsten oxide residue from a prior semiconductor fabrication process) on the semiconductor wafer 102, such as according to the following equation:

$$WO 2 + 2 H 2 O + 2 {e}^{-} \to W + 4 {OH}^{-} .$$

In some embodiments, the first cleaning fluid comprises hydrogen (e.g., H₂). In some embodiments, the first reverse reaction comprises a reaction (e.g., a redox reaction) between hydrogen of the first cleaning fluid and metal oxide (e.g., oxidized metal residue from a prior semiconductor fabrication process) on the semiconductor wafer 102. In some embodiments, the first reverse reaction comprises a reaction (e.g., a redox reaction) between hydrogen of the first cleaning fluid and tungsten oxide (e.g., tungsten oxide residue from a prior semiconductor fabrication process) on the semiconductor wafer 102, such as according to the following equation:

$$WO 2 + 2 H 2 + 2 {e}^{-} \to W + 2 H 2 O .$$

In some embodiments, a speed of the first reverse reaction increases based upon at least one of (i) an increase of a temperature associated with the first cleaning fluid, (ii) an increase of a temperature associated with water (e.g., de-ionized water) of the first cleaning fluid, or (iii) an increase of a temperature associated with hydrogen of the first cleaning fluid. In some embodiments, a speed associated with the first reverse reaction is about r=k*Δ[C(WOx)]/Δt, where at least one of (i) k=A exp(−Ea/RT) (Arrhenius equation), (ii) A corresponds to frequency factor, (iii) Ea corresponds to activation energy, (iv) R corresponds to gas constant, or (v) T corresponds to a temperature value (e.g., a value corresponding to at least one of the temperature associated with the first cleaning fluid, the temperature associated with the water of the first cleaning fluid, the temperature associated with the hydrogen of the first cleaning fluid, or a temperature associated with the semiconductor wafer 102). In some embodiments, at least one of the speed r or the value k is a function of the temperature value T, wherein an increase of the temperature value T is associated with an increase (e.g., an exponential increase) of at least one of the speed r or the value k. In some embodiments, the cleaning apparatus 100 comprises a first fluid temperature controller configured to apply heat to a fluid (e.g., water and/or hydrogen) to produce a heated fluid, wherein the first cleaning fluid applied to the semiconductor wafer 102 comprises the heated fluid.

In some embodiments, the wafer cleaning assembly 120 comprises a second set of outlets (e.g., a second set of one or more outlets) configured to emit a second cleaning fluid to the second brush 108. In some embodiments, the second set of outlets are defined by the second roller 110. In some embodiments, the second set of outlets are defined by a portion, of the second roller 110, that is at least one of surrounded by or adjacent to the second brush 108. In some embodiments, the second roller 110 comprises a second roller inlet 155 configured to receive the second cleaning fluid. In some embodiments, a conduit 154 is used to conduct the second cleaning fluid to and/or through the second roller inlet 155 into the second roller 110. In some embodiments, the second roller 110 defines a conduit through which the second cleaning fluid travels from the second roller inlet 155 to the second set of outlets to be emitted through the second set of outlets.

In some embodiments, during (and/or prior to) the cleaning process, the second cleaning fluid is dispensed from the second set of outlets to at least one of the second brush 108 or the second surface of the semiconductor wafer 102. In some embodiments, the second brush 108 is soaked with at least some of the second cleaning fluid that was emitted by the second set of outlets. In some embodiments, during the brushing process, at least some of the second cleaning fluid is transferred from the second brush 108 to the second surface of the semiconductor wafer 102 while at least one of (i) the second brush 108 is in contact with the second surface of the semiconductor wafer 102, (ii) the second brush 108 is rotated in the rotational direction 116, or (iii) the semiconductor wafer 102 is rotated in the rotational direction 121. In some embodiments, the brushing process removes one or more contaminants (e.g., residue from a prior semiconductor fabrication process) from the semiconductor wafer 102, such as due, at least in part, to (i) mechanical action of the second brush 108 on the semiconductor wafer 102 and/or contaminants on the semiconductor wafer 102 (e.g., the mechanical action dislodges the contaminants), (ii) a second reverse reaction of an oxidized metal caused by application of the second cleaning fluid to the semiconductor wafer 102, or (iii) washing away of dislodged contaminants by the second cleaning fluid. In some embodiments, the mechanical action depends upon at least one of (i) a type of the second brush 108, (ii) a material of the second brush 108, or (iii) an amount of the second cleaning fluid applied to the semiconductor wafer 102. In some embodiments, the second brush 108 comprises at least one of a PVA brush, a nylon brush, a polyurethane brush, a polyester brush, a PTFE brush, or other type of brush. In some embodiments, at least some of the second cleaning fluid dispensed during the cleaning process is emitted from the second set of outlets towards the semiconductor wafer 102 (e.g., at least some of the second cleaning fluid is dispensed directly onto the second surface of the semiconductor wafer 102 from the second set of outlets).

In some embodiments, the second reverse reaction comprises a reduction-oxidation (redox) reaction. In some embodiments, the second cleaning fluid comprises water (e.g., de-ionized water). In some embodiments, the second reverse reaction comprises a reaction (e.g., a redox reaction) between water (e.g., de-ionized water) of the second cleaning fluid and metal oxide (e.g., oxidized metal residue from a prior semiconductor fabrication process) on the semiconductor wafer 102. In some embodiments, the second reverse reaction comprises a reaction (e.g., a redox reaction) between water (e.g., de-ionized water) of the second cleaning fluid and tungsten oxide (e.g., tungsten oxide residue from a prior semiconductor fabrication process) on the semiconductor wafer 102, such as according to the following equation: WO2+2H2O+2e⁻→W+4OH⁻.

In some embodiments, the second cleaning fluid comprises hydrogen (e.g., H₂). In some embodiments, the second reverse reaction comprises a reaction (e.g., a redox reaction) between hydrogen of the second cleaning fluid and metal oxide (e.g., oxidized metal residue from a prior semiconductor fabrication process) on the semiconductor wafer 102. In some embodiments, the second reverse reaction comprises a reaction (e.g., a redox reaction) between hydrogen of the second cleaning fluid and tungsten oxide (e.g., tungsten oxide residue from a prior semiconductor fabrication process) on the semiconductor wafer 102, such as according to the following equation: WO2+2H2+2e⁻→W+2H2O.

In some embodiments, a speed of the second reverse reaction increases based upon at least one of (i) an increase of a temperature associated with the second cleaning fluid, (ii) an increase of a temperature associated with water (e.g., de-ionized water) of the second cleaning fluid, or (iii) an increase of a temperature associated with hydrogen of the second cleaning fluid. In some embodiments, a speed associated with the second reverse reaction is about r=k*Δ[C(WOx)]/Δt, where at least one of (i) k=A exp(−Ea/RT) (Arrhenius equation), (ii) A corresponds to frequency factor, (iii) Ea corresponds to activation energy, (iv) R corresponds to gas constant, or (v) T corresponds to a temperature value (e.g., a value corresponding to at least one of the temperature associated with the first cleaning fluid, the temperature associated with the water of the first cleaning fluid, the temperature associated with the hydrogen of the first cleaning fluid, or a temperature associated with the semiconductor wafer 102). In some embodiments, at least one of the speed r or the value k is a function of the temperature value T, wherein an increase of the temperature value T is associated with an increase (e.g., an exponential increase) of at least one of the speed r or the value k. In some embodiments, the cleaning apparatus 100 comprises a second fluid temperature controller configured to apply heat to a fluid (e.g., water and/or hydrogen) to produce a second heated fluid, wherein the second cleaning fluid applied to the semiconductor wafer 102 comprises the second heated fluid. In some embodiments, the first cleaning fluid (dispensed from the first set of outlets) and the second cleaning fluid (dispensed from the first set of outlets) are from a single source of cleaning fluid.

FIG. 1B illustrates a first side view of the cleaning apparatus 100, in accordance with some embodiments. In some embodiments, an angle θ associated with the first brush 104 (and/or the first roller 106) relative to the semiconductor wafer 102 is greater than 0 degrees. FIG. 1C illustrates a second side view of the cleaning apparatus 100, in accordance with some embodiments.

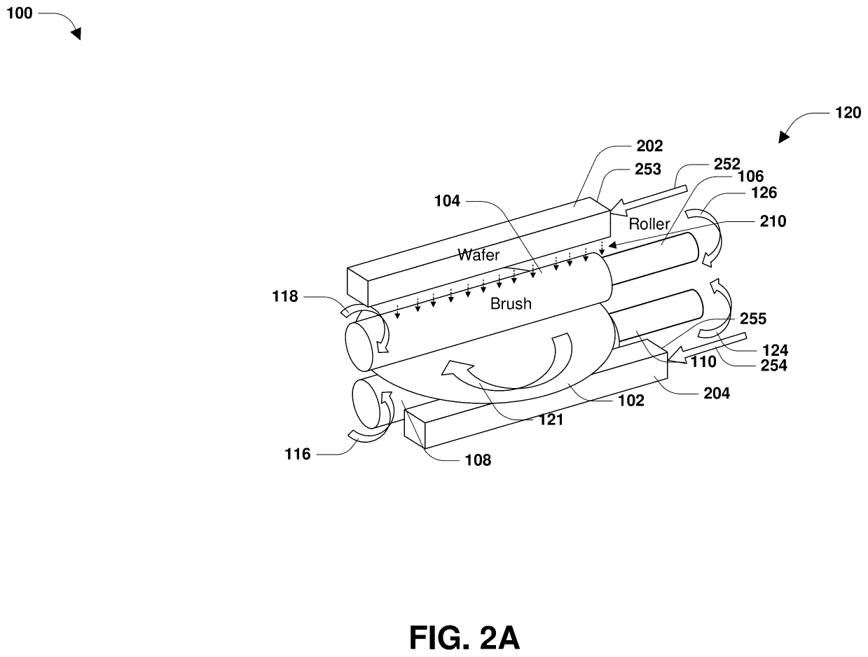

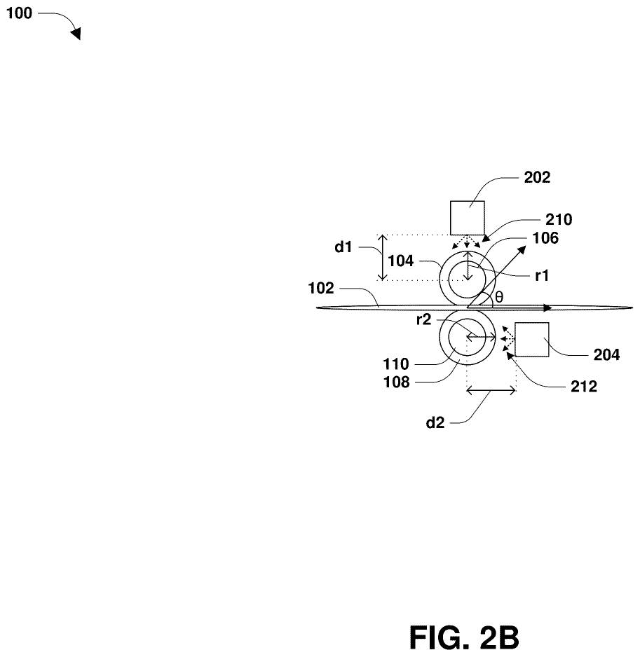

FIGS. 2A-2B illustrate the cleaning apparatus 100 according to some embodiments. FIG. 2A illustrates a perspective view of the cleaning apparatus 100, in accordance with some embodiments. In some embodiments, the wafer cleaning assembly 120 comprises a set of fluid dispensers (e.g., a set of one or more fluid dispensers). In some embodiments, a dispenser of the set of fluid dispensers is configured to dispense cleaning fluid (e.g., a fluid comprising hydrogen and water, such as deionized water) to at least one of the first brush 104 or the semiconductor wafer 102.

In some embodiments, the set of fluid dispensers comprises a first fluid dispenser 202 configured to dispense a third cleaning fluid (e.g., a fluid comprising hydrogen and water, such as deionized water) to at least one of the first brush 104 or the semiconductor wafer 102. In some embodiments, the first fluid dispenser 202 defines a third set of outlets (e.g., a third set of one or more outlets) configured to emit the third cleaning fluid. In some embodiments, the first fluid dispenser 202 comprises a first dispenser inlet 253 configured to receive the third cleaning fluid. In some embodiments, a conduit 252 is used to conduct the third cleaning fluid to and/or through the first dispenser inlet 253 into the first fluid dispenser 202. In some embodiments, the first fluid dispenser 202 defines a conduit through which the third cleaning fluid travels from the first dispenser inlet 253 to the third set of outlets to be emitted through the third set of outlets.

In some embodiments, during (and/or prior to) the cleaning process, the third cleaning fluid (e.g., fluid 210, flow of which is shown in FIGS. 2A-2B with dashed-line arrows) is dispensed by the first fluid dispenser 202 to at least one of the first brush 104 or the first surface of the semiconductor wafer 102. In some embodiments, the first brush 104 is soaked with at least some of the third cleaning fluid. In some embodiments, during the brushing process, at least some of the third cleaning fluid is transferred from the first brush 104 to the first surface of the semiconductor wafer 102 while at least one of (i) the first brush 104 is in contact with the first surface of the semiconductor wafer 102, (ii) the first brush 104 is rotated in the rotational direction 118, or (iii) the semiconductor wafer 102 is rotated in the rotational direction 121. In some embodiments, the brushing process removes one or more contaminants (e.g., residue from a prior semiconductor fabrication process) from the semiconductor wafer 102, such as due, at least in part, to (i) mechanical action of the first brush 104 on the semiconductor wafer 102 and/or contaminants on the semiconductor wafer 102 (e.g., the mechanical action dislodges the contaminants), (ii) a third reverse reaction of an oxidized metal caused by application of the third cleaning fluid to the semiconductor wafer 102, or (iii) washing away of dislodged contaminants by the third cleaning fluid. In some embodiments, the mechanical action depends upon an amount of the third cleaning fluid applied to the semiconductor wafer 102. In some embodiments, at least some of the third cleaning fluid dispensed during the cleaning process is emitted from the third set of outlets towards the semiconductor wafer 102 (e.g., at least some of the third cleaning fluid is dispensed directly onto the first surface of the semiconductor wafer 102 from the third set of outlets).

In some embodiments, the third reverse reaction comprises a reduction-oxidation (redox) reaction. In some embodiments, the third cleaning fluid comprises water (e.g., de-ionized water). In some embodiments, the third reverse reaction comprises a reaction (e.g., a redox reaction) between water (e.g., de-ionized water) of the third cleaning fluid and metal oxide (e.g., oxidized metal residue from a prior semiconductor fabrication process) on the semiconductor wafer 102. In some embodiments, the third reverse reaction comprises a reaction (e.g., a redox reaction) between water (e.g., de-ionized water) of the third cleaning fluid and tungsten oxide (e.g., tungsten oxide residue from a prior semiconductor fabrication process) on the semiconductor wafer 102, such as according to the following equation:

$$WO 2 + 2 H 2 O + 2 {e}^{-} \to W + 4 {OH}^{-} .$$

In some embodiments, the third cleaning fluid comprises hydrogen (e.g., H₂). In some embodiments, the third reverse reaction comprises a reaction (e.g., a redox reaction) between hydrogen of the third cleaning fluid and metal oxide (e.g., oxidized metal residue from a prior semiconductor fabrication process) on the semiconductor wafer 102. In some embodiments, the third reverse reaction comprises a reaction (e.g., a redox reaction) between hydrogen of the third cleaning fluid and tungsten oxide (e.g., tungsten oxide residue from a prior semiconductor fabrication process) on the semiconductor wafer 102, such as according to the following equation: WO2+2H2+2e⁻→W+2H2O.

In some embodiments, a speed of the third reverse reaction increases based upon at least one of (i) an increase of a temperature associated with the third cleaning fluid, (ii) an increase of a temperature associated with water (e.g., de-ionized water) of the third cleaning fluid, or (iii) an increase of a temperature associated with hydrogen of the third cleaning fluid. In some embodiments, a speed associated with the third reverse reaction is about r=k*Δ[C(WOx)]/Δt, where at least one of (i) k=A exp(−Ea/RT) (Arrhenius equation), (ii) A corresponds to frequency factor, (iii) Ea corresponds to activation energy, (iv) R corresponds to gas constant, or (v) T corresponds to a temperature value (e.g., a value corresponding to at least one of the temperature associated with the third cleaning fluid, the temperature associated with the water of the third cleaning fluid, the temperature associated with the hydrogen of the third cleaning fluid, or a temperature associated with the semiconductor wafer 102). In some embodiments, at least one of the speed r or the value k is a function of the temperature value T, wherein an increase of the temperature value T is associated with an increase (e.g., an exponential increase) of at least one of the speed r or the value k. In some embodiments, the cleaning apparatus 100 comprises a third fluid temperature controller configured to apply heat to a fluid (e.g., water and/or hydrogen) to produce a heated fluid, wherein the third cleaning fluid applied to the semiconductor wafer 102 comprises the heated fluid.

In some embodiments, the set of fluid dispensers comprises a second fluid dispenser 204 configured to dispense a fourth cleaning fluid (e.g., a fluid comprising hydrogen and water, such as deionized water) to at least one of the second brush 108 or the semiconductor wafer 102. In some embodiments, the second fluid dispenser 204 defines a fourth set of outlets (e.g., a fourth set of one or more outlets) configured to emit the fourth cleaning fluid. In some embodiments, the second fluid dispenser 204 comprises a second dispenser inlet 255 configured to receive the fourth cleaning fluid. In some embodiments, a conduit 254 is used to conduct the fourth cleaning fluid to and/or through the second dispenser inlet 255 into the second fluid dispenser 204. In some embodiments, the second fluid dispenser 204 defines a conduit through which the fourth cleaning fluid travels from the second dispenser inlet 255 to the fourth set of outlets to be emitted through the fourth set of outlets.

In some embodiments, during (and/or prior to) the cleaning process, the fourth cleaning fluid (e.g., fluid 212 shown in FIG. 2B, flow of which is shown in FIG. 2B with dashed-line arrows) is dispensed by the second fluid dispenser 204 to at least one of the second brush 108 or the first surface of the semiconductor wafer 102. In some embodiments, the second brush 108 is soaked with at least some of the fourth cleaning fluid. In some embodiments, during the brushing process, at least some of the fourth cleaning fluid is transferred from the second brush 108 to the first surface of the semiconductor wafer 102 while at least one of (i) the second brush 108 is in contact with the first surface of the semiconductor wafer 102, (ii) the second brush 108 is rotated in the rotational direction 116, or (iii) the semiconductor wafer 102 is rotated in the rotational direction 121. In some embodiments, the brushing process removes one or more contaminants (e.g., residue from a prior semiconductor fabrication process) from the semiconductor wafer 102, such as due, at least in part, to (i) mechanical action of the second brush 108 on the semiconductor wafer 102 and/or contaminants on the semiconductor wafer 102 (e.g., the mechanical action dislodges the contaminants), (ii) a fourth reverse reaction of an oxidized metal caused by application of the fourth cleaning fluid to the semiconductor wafer 102, or (iii) washing away of dislodged contaminants by the fourth cleaning fluid. In some embodiments, the mechanical action depends upon an amount of the fourth cleaning fluid applied to the semiconductor wafer 102. In some embodiments, at least some of the fourth cleaning fluid dispensed during the cleaning process is emitted from the fourth set of outlets towards the semiconductor wafer 102 (e.g., at least some of the fourth cleaning fluid is dispensed directly onto the first surface of the semiconductor wafer 102 from the fourth set of outlets).

In some embodiments, the fourth reverse reaction comprises a reduction-oxidation (redox) reaction. In some embodiments, the fourth cleaning fluid comprises water (e.g., de-ionized water). In some embodiments, the fourth reverse reaction comprises a reaction (e.g., a redox reaction) between water (e.g., de-ionized water) of the fourth cleaning fluid and metal oxide (e.g., oxidized metal residue from a prior semiconductor fabrication process) on the semiconductor wafer 102. In some embodiments, the fourth reverse reaction comprises a reaction (e.g., a redox reaction) between water (e.g., de-ionized water) of the fourth cleaning fluid and tungsten oxide (e.g., tungsten oxide residue from a prior semiconductor fabrication process) on the semiconductor wafer 102, such as according to the following equation: WO2+2H2O+2e⁻→W+4OH⁻.

In some embodiments, the fourth cleaning fluid comprises hydrogen (e.g., H₂). In some embodiments, the fourth reverse reaction comprises a reaction (e.g., a redox reaction) between hydrogen of the fourth cleaning fluid and metal oxide (e.g., oxidized metal residue from a prior semiconductor fabrication process) on the semiconductor wafer 102. In some embodiments, the fourth reverse reaction comprises a reaction (e.g., a redox reaction) between hydrogen of the fourth cleaning fluid and tungsten oxide (e.g., tungsten oxide residue from a prior semiconductor fabrication process) on the semiconductor wafer 102, such as according to the following equation: WO2+2H2+2e⁻→W+2H2O.

In some embodiments, a speed of the fourth reverse reaction increases based upon at least one of (i) an increase of a temperature associated with the fourth cleaning fluid, (ii) an increase of a temperature associated with water (e.g., de-ionized water) of the fourth cleaning fluid, or (iii) an increase of a temperature associated with hydrogen of the fourth cleaning fluid. In some embodiments, a speed associated with the fourth reverse reaction is about r=k*Δ[C(WOx)]/Δt, where at least one of (i) k=A exp(−Ea/RT) (Arrhenius equation), (ii) A corresponds to frequency factor, (iii) Ea corresponds to activation energy, (iv) R corresponds to gas constant, or (v) T corresponds to a temperature value (e.g., a value corresponding to at least one of the temperature associated with the fourth cleaning fluid, the temperature associated with the water of the fourth cleaning fluid, the temperature associated with the hydrogen of the fourth cleaning fluid, or a temperature associated with the semiconductor wafer 102). In some embodiments, at least one of the speed r or the value k is a function of the temperature value T, wherein an increase of the temperature value T is associated with an increase (e.g., an exponential increase) of at least one of the speed r or the value k. In some embodiments, the cleaning apparatus 100 comprises a fourth fluid temperature controller configured to apply heat to a fluid (e.g., water and/or hydrogen) to produce a heated fluid, wherein the fourth cleaning fluid applied to the semiconductor wafer 102 comprises the heated fluid.

In some embodiments, at least two of (i) the first cleaning fluid (dispensed from the first set of outlets defined by the first roller 106), the second cleaning fluid (dispensed from the second set of outlets defined by the second roller 110), the third cleaning fluid (dispensed from the third set of outlets defined by the first fluid dispenser 202), or the fourth cleaning fluid (dispensed from the fourth set of outlets defined by the second fluid dispenser 204) are from a single source of cleaning fluid. In some embodiments, a single fluid temperature controller is used to heat at least two of the first cleaning fluid, the second cleaning fluid, the third cleaning fluid, or the fourth cleaning fluid. In some embodiments, at least two of (i) the first cleaning fluid (dispensed from the first set of outlets defined by the first roller 106), (ii) the second cleaning fluid (dispensed from the second set of outlets defined by the second roller 110), (iii) the third cleaning fluid (dispensed from the third set of outlets defined by the first fluid dispenser 202), or (iv) the fourth cleaning fluid (dispensed from the fourth set of outlets defined by the second fluid dispenser 204) are from different sources of cleaning fluid.

In some embodiments, the set of fluid dispensers comprises one or more other fluid dispensers (in addition to or as an alternative to the first fluid dispenser 202 and/or the second fluid dispenser 204). In some embodiments, during (and/or prior to) the cleaning process, a fluid dispenser of the one or more other fluid dispensers is operated to dispense a cleaning fluid (e.g., a fluid, such as a temperature-controlled fluid, comprising hydrogen and water, such as deionized water) using one or more of the techniques provided herein with respect to at least one of first fluid dispenser 202 or the second fluid dispenser 204, wherein the cleaning fluid is applied to the semiconductor wafer 102 (e.g., applied to the semiconductor wafer 102 via a brush and/or directly to the semiconductor wafer 102) during the cleaning process. In some embodiments, one or more contaminants (e.g., residue from a prior semiconductor fabrication process) are removed from the semiconductor wafer 102, such as due, at least in part, to a reverse reaction of an oxidized metal caused by application of the cleaning fluid to the semiconductor wafer 102 or washing away of dislodged contaminants by the cleaning fluid. In some embodiments, the reverse reaction comprises a reaction (e.g., a redox reaction) between hydrogen and/or water of the cleaning fluid and tungsten oxide (e.g., tungsten oxide residue from a prior semiconductor fabrication process) on the semiconductor wafer 102. In some embodiments, a temperature associated with the cleaning fluid is controlled using a fluid temperature controller (e.g., at least one of the first fluid temperature controller, the second fluid temperature controller, the third fluid temperature controller, or the fourth fluid temperature controller) to control a speed of the reverse reaction. In some embodiments, the temperature associated with the cleaning fluid is increased to increase a speed of the reverse reaction.

In some embodiments, during the cleaning process, at least one of (i) the first cleaning fluid is dispensed from the first set of outlets defined by the first roller 106 and/or applied to the semiconductor wafer 102, (ii) the second cleaning fluid is dispensed from the second set of outlets defined by the second roller 110 and/or applied to the semiconductor wafer 102, (iii) the third cleaning fluid is dispensed from the third set of outlets defined by the first fluid dispenser 202 and/or applied to the semiconductor wafer 102, (iv) the fourth cleaning fluid is dispensed from the fourth set of outlets defined by the second fluid dispenser 204 and/or applied to the semiconductor wafer 102, or (v) cleaning fluid (e.g., fluid, such as a temperature-controlled fluid, comprising hydrogen and water, such as deionized water) is dispensed from the one or more other fluid dispensers defined by the second fluid dispenser 204 and/or applied to the semiconductor wafer 102.

FIG. 2B illustrates a side view of the cleaning apparatus 100, in accordance with some embodiments. In some embodiments, each fluid dispenser of one, some or all of the set of fluid dispensers has a separation distance from a point (e.g., a center point) associated with a corresponding brush and/or a corresponding roller. In some embodiments, the separation distance is at least one of (i) at least about a minimum separation distance or (ii) at most about a maximum separation distance. In some embodiments, at least one of the minimum separation distance or the maximum separation distance is based upon a dimension (e.g., at least one of a radius, a diameter, a circumference, etc.) associated with the corresponding brush and/or the corresponding roller.

In some embodiments, the first fluid dispenser 202 has a first separation distance d1 (shown in FIG. 2B) from a point associated with the first brush 104 and/or the first roller 106 (e.g., a center point of the first brush 104 and/or the first roller 106). In some embodiments, the first separation distance d1 is at least one of (i) at least about a first minimum separation distance or (ii) at most about a first maximum separation distance. In some embodiments, at least one of the first minimum separation distance or the first maximum separation distance is based upon a dimension (e.g., at least one of a radius, a diameter, a circumference, etc.) associated with the first brush 104 and/or the first roller 106. In some embodiments, the first minimum separation distance is at least one of (i) about half of a radius r1 of the first brush 104 or (ii) about equal to the radius r1 of the first brush 104. In some embodiments, the first maximum separation distance is about ten times the radius r1 of the first brush 104. Other values of the first minimum separation distance and/or the first maximum separation distance are within the scope of the present disclosure.

In some embodiments, the second fluid dispenser 204 has a second separation distance d2 from a point associated with the second brush 108 and/or the second roller 110 (e.g., a center point of the second brush 108 and/or the second roller 110). In some embodiments, the second separation distance d2 is at least one of (i) at least about a second minimum separation distance or (ii) at most about a second maximum separation distance. In some embodiments, at least one of the second minimum separation distance or the second maximum separation distance is based upon a dimension (e.g., at least one of a radius, a diameter, a circumference, etc.) associated with the second brush 108 and/or the second roller 110. In some embodiments, the second minimum separation distance is at least one of (i) about half of a radius r2 of the second brush 108 or (ii) about equal to the radius r2 of the second brush 108. In some embodiments, the second maximum separation distance is about ten times the radius r2 of the second brush 108. Other values of the second minimum separation distance and/or the second maximum separation distance are within the scope of the present disclosure.

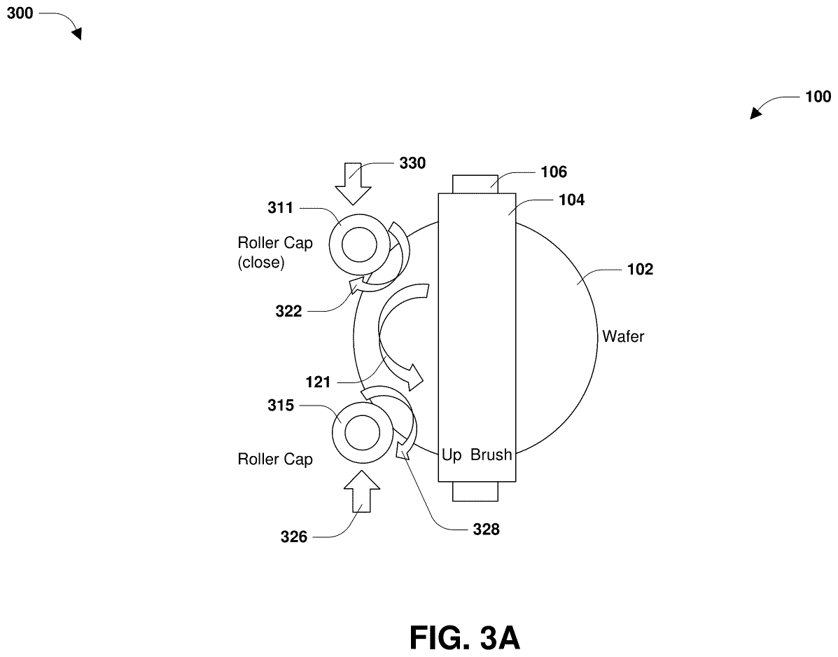

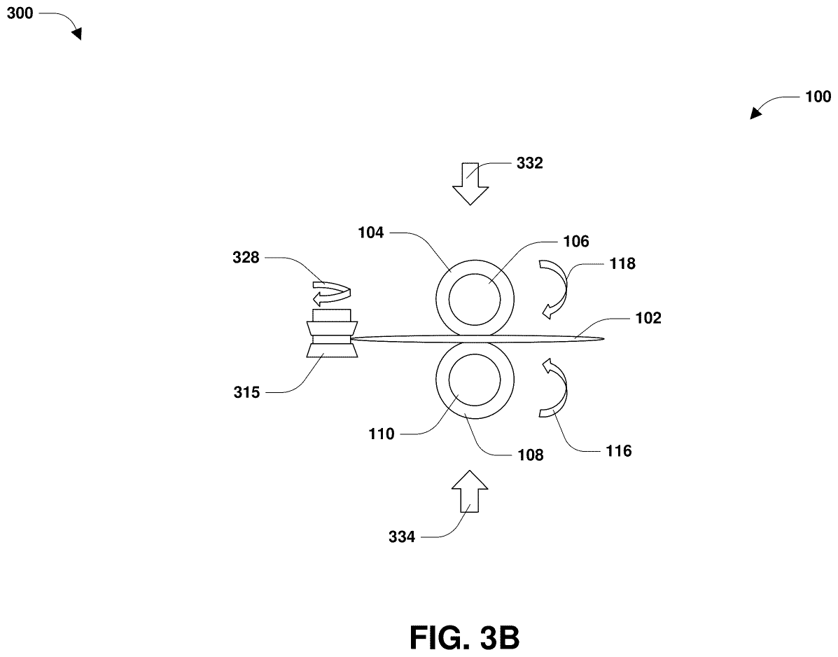

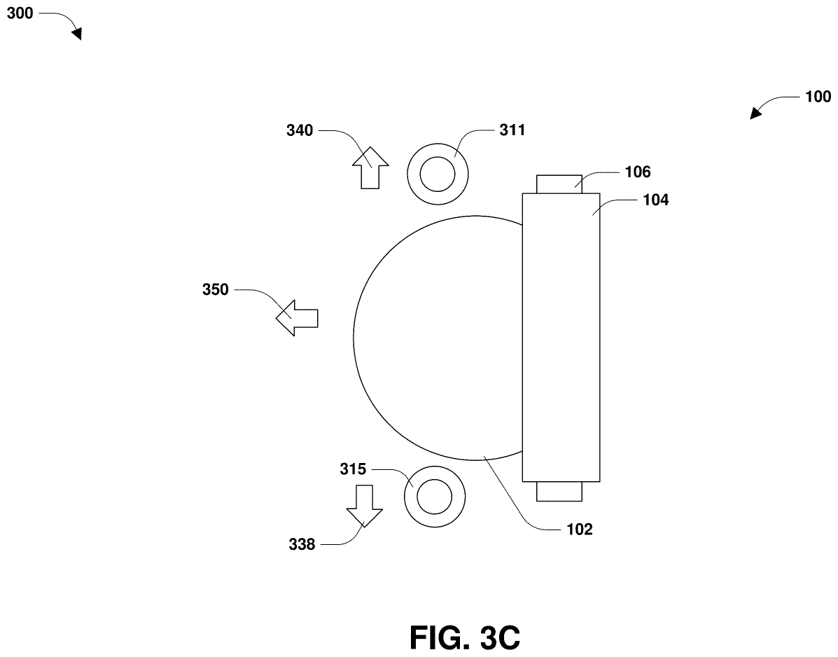

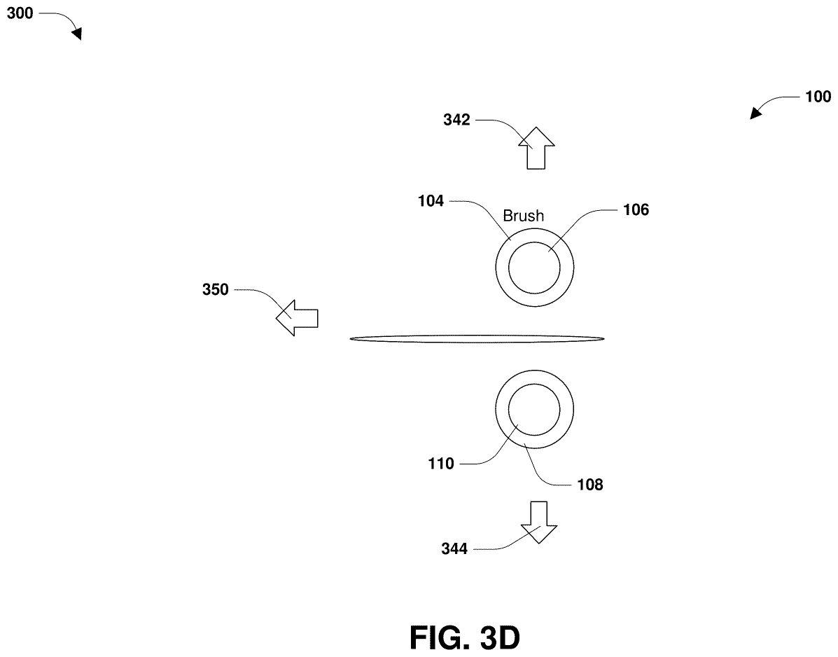

FIGS. 3A-3D illustrate a scenario 300 associated with the cleaning process according to some embodiments. FIG. 3A illustrates a top view of the cleaning apparatus 100 during a cleaning stage of the cleaning process, in accordance with some embodiments. FIG. 3B illustrates a side view of the cleaning apparatus 100 during the cleaning stage of the cleaning process, in accordance with some embodiments.

In some embodiments, the cleaning apparatus 100 comprises a wafer support assembly to support the semiconductor wafer 102 in the cleaning position. In some embodiments, the wafer support assembly comprises a set of roller caps (e.g., a set of one or more roller caps) configured to rotate the semiconductor wafer 102 while the semiconductor wafer 102 is in the cleaning position. In some embodiments, the set of roller caps comprises at least one of a first roller cap 311 or a second roller cap 315.

In some embodiments, prior to (and/or during) the cleaning stage of the cleaning process, the set of roller caps undergo a roller cap engagement process to enter a roller cap engagement state. FIG. 3A depicts the set of roller caps in the roller cap engagement state relative to the semiconductor wafer 102 in accordance with some embodiments. In some embodiments, when the set of roller caps are in the roller cap engagement state, at least one of (i) the first roller cap 311 is in contact with and/or supports the semiconductor wafer 102, or (ii) the second roller cap 315 is in contact with and/or supports the semiconductor wafer 102. In some embodiments, the roller cap engagement process comprises at least one of (i) movement of the first roller cap 311 in a direction 330 (shown in FIG. 3A), or (ii) movement of the second roller cap 315 in a direction 326 (shown in FIG. 3A).

In some embodiments, prior to (and/or during) the cleaning stage of the cleaning process, the set of brushes undergo a brush engagement process to enter a brush engagement state. FIG. 3B depicts the set of brushes in the brush engagement state relative to the semiconductor wafer 102 in accordance with some embodiments. In some embodiments, when the set of brushes are in the brush engagement state, at least one of (i) the first brush 104 is in contact with the semiconductor wafer 102, or (ii) the second brush 108 is in contact with and/or supports the semiconductor wafer 102. In some embodiments, the brush engagement process comprises at least one of (i) movement of the first brush 104 (and/or the first roller 106) in a direction 332 (shown in FIG. 3B), or (ii) movement of the second brush 108 (and/or the second roller 110) in a direction 334 (shown in FIG. 3B).

In some embodiments, the semiconductor wafer 102 is rotated in the rotational direction 121 using the set of roller caps. In some embodiments, during the cleaning stage of the cleaning process, at least one of (i) the first roller cap 311 rotates in a rotational direction 322 while the first roller cap 311 is in contact with the semiconductor wafer 102, or (ii) the second roller cap 315 rotates in a rotational direction 328 while the second roller cap 315 is in contact with the semiconductor wafer 102. In some embodiments, the rotation of the first roller cap 311 in the rotational direction 322 induces a rotational force to the semiconductor wafer 102 in the rotational direction 121 (that causes the semiconductor wafer 102 to rotate in the rotational direction 121, for example). In some embodiments, the rotation of the second roller cap 315 in the rotational direction 328 induces a rotational force to the semiconductor wafer 102 in the rotational direction 121 (that causes the semiconductor wafer 102 to rotate in the rotational direction 121, for example).

In some embodiments, during the cleaning stage of the cleaning process, at least one of (i) the first cleaning fluid is dispensed from the first set of outlets defined by the first roller 106 to the first brush 104, (ii) the first brush 104 is in contact with the first surface of the semiconductor wafer 102, (iii) at least some of the first cleaning fluid is transferred from the first brush 104 to the semiconductor wafer 102, (iv) the first brush 104 is rotated in the rotational direction 118, (v) the second cleaning fluid is dispensed from the second set of outlets defined by the second roller 110 to the second brush 108, (vi) the second brush 108 is in contact with the second surface of the semiconductor wafer 102, (vii) at least some of the second cleaning fluid is transferred from the second brush 108 to the semiconductor wafer 102, or (viii) the second brush 108 is rotated in the rotational direction 116.

FIG. 3C illustrates a top view of the cleaning apparatus 100 during a transfer stage of the cleaning process, in accordance with some embodiments. FIG. 3D illustrates a side view of the cleaning apparatus 100 during the transfer stage of the cleaning process, in accordance with some embodiments.

In some embodiments, during the transfer stage of the cleaning process, the set of roller caps undergo a roller cap disengagement process to leave the roller cap engagement state and/or enter a roller cap disengagement state. FIG. 3C depicts the set of roller caps in the roller cap disengagement state relative to the semiconductor wafer 102 in accordance with some embodiments. In some embodiments, when the set of roller caps are in the roller cap disengagement state, at least one of (i) the first roller cap 311 is not in contact with and/or is not engaged with the semiconductor wafer 102, or (ii) the second roller cap 315 is in contact with and/or is not engaged with the semiconductor wafer 102. In some embodiments, the roller cap disengagement process comprises at least one of (i) movement of the first roller cap 311 in a direction 340 (shown in FIG. 3C), or (ii) movement of the second roller cap 315 in a direction 338 (shown in FIG. 3C).

In some embodiments, during the transfer stage of the cleaning process, the set of brushes undergo a brush disengagement process to leave the brush engagement state and/or enter a brush disengagement state. FIG. 3C depicts the set of brushes in the brush disengagement state relative to the semiconductor wafer 102 in accordance with some embodiments. In some embodiments, when the set of brushes are in the brush disengagement state, at least one of (i) the first brush 104 is not in contact with and/or is not engaged with the semiconductor wafer 102, or (ii) the second brush 108 is in contact with and/or is not engaged with the semiconductor wafer 102. In some embodiments, the brush disengagement process comprises at least one of (i) movement of the first brush 104 (and/or the first roller 106) in a direction 342 (shown in FIG. 3D), or (ii) movement of the second roller cap 315 in a direction 344 (shown in FIG. 3D).

In some embodiments, during the transfer stage, at least one of (i) the set of roller caps is in the in the roller cap disengagement state, (ii) the set of brushes is in the brush disengagement state, or (iii) the semiconductor wafer 102 is transferred from a first cleaning environment of the cleaning apparatus 100 to outside the first cleaning environment by moving the semiconductor wafer 102 in a direction 350.

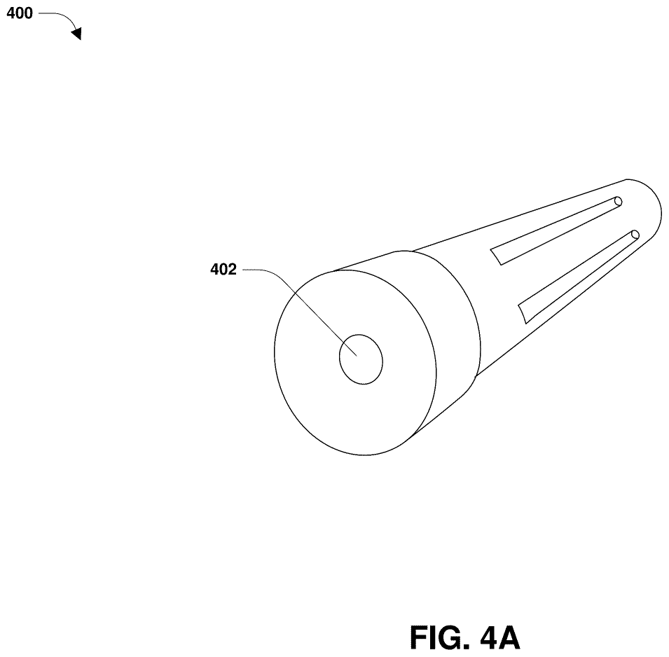

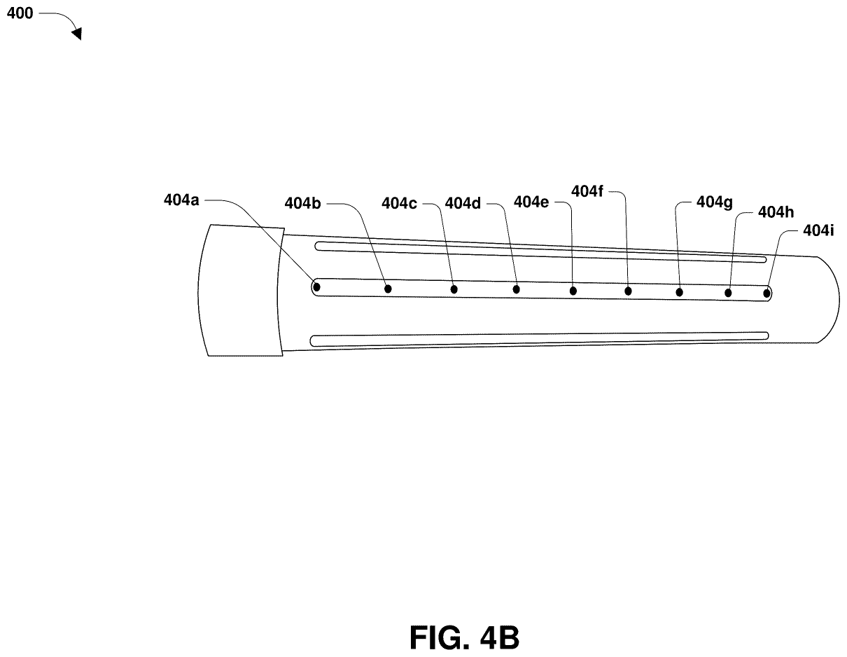

FIGS. 4A-4B illustrate a roller 400 in accordance with some embodiments. FIG. 4A illustrates a perspective view of the roller 400, according to some embodiments. In some embodiments, the roller 400 comprises at least one of the first roller 106, the second roller 110, or other roller of the cleaning apparatus 100. In some embodiments, the roller 400 defines an inlet 402 (e.g., the first roller inlet 153, the second roller inlet 155) configured to receive a cleaning fluid (e.g., the first cleaning fluid, the second cleaning fluid). FIG. 4B illustrates a top view of the roller 400, according to some embodiments. In some embodiments, the roller 400 defines a set of outlets (e.g., a set of one or more outlets), such as at least one of the first set of outlets or the second set of outlets. In some embodiments, the set of outlets of the roller 400 comprises at least one of an outlet 404a, an outlet 404b, an outlet 404c, an outlet 404d, an outlet 404e, an outlet 404f, an outlet 404g, an outlet 404h, or an outlet 404i. In some embodiments, the roller 400 defines a conduit through which the cleaning fluid travels from the inlet 402 to the set of outlets to be emitted through the set of outlets (to a brush of the set of brushes and/or to the semiconductor wafer 102).

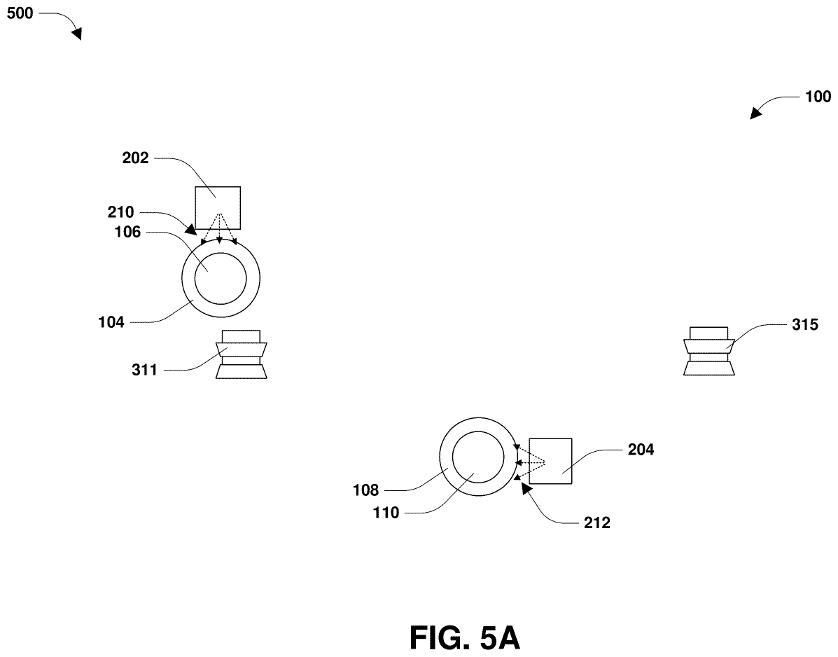

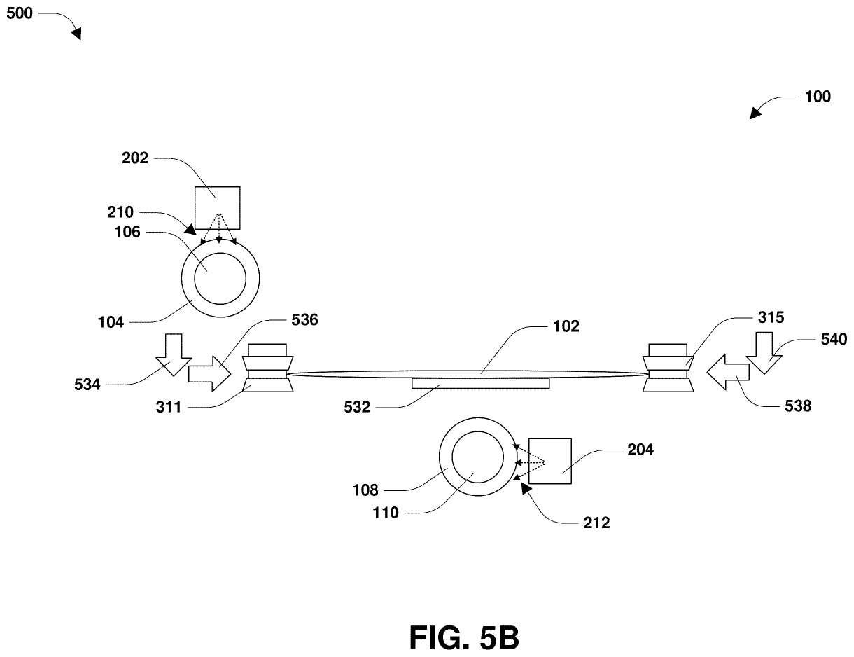

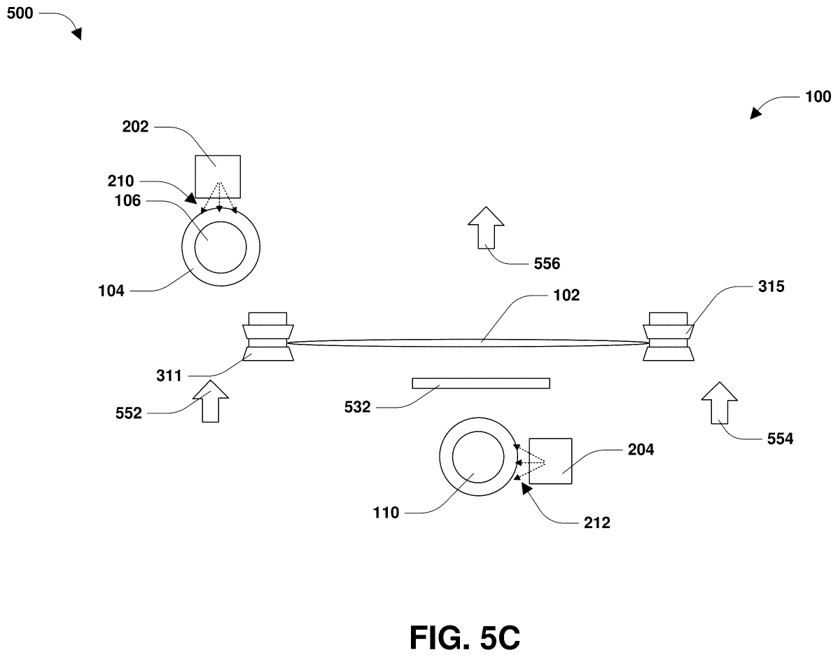

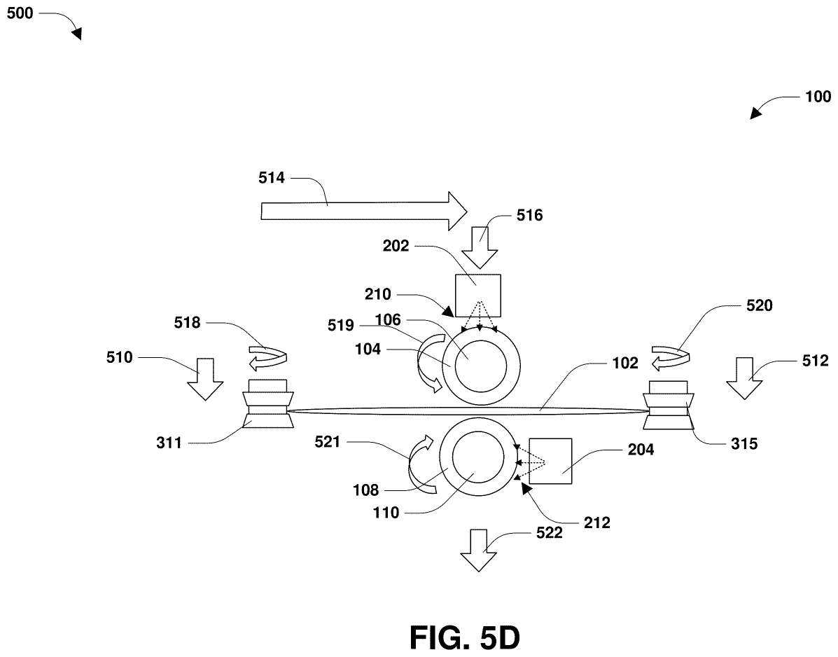

FIGS. 5A-5D illustrate a scenario 500 associated with the cleaning process according to some embodiments. In some embodiments, in the scenario 500, the cleaning apparatus 100 uses the set of fluid dispensers to dispense cleaning fluid (e.g., a fluid, such as a temperature-controlled fluid, comprising hydrogen and water, such as deionized water) for application to the semiconductor wafer 102.

FIG. 5A illustrates a side view of the cleaning apparatus 100 during an idle stage of the cleaning apparatus 100, in accordance with some embodiments. In some embodiments, during the idle stage, at least one of (i) the first fluid dispenser 202 dispenses the third cleaning fluid (e.g., fluid 210, flow of which is shown in FIGS. 5A-5D with dashed-line arrows) to the first brush 104, (ii) the second fluid dispenser 204 dispenses the fourth cleaning fluid (e.g., fluid 212, flow of which is shown in FIGS. 5A-5D with dashed-line arrows) to the second brush 108, (iii) the set of roller caps is in a roller cap idle state, or (iv) the set of brushes is in a brush idle state. FIG. 5A depicts the set of roller caps in the roller cap idle state in accordance with some embodiments. FIG. 5A depicts the set of brushes in the brush idle state in accordance with some embodiments.

FIGS. 5B-5C illustrate side views of the cleaning apparatus 100 during a second transfer stage of the cleaning process, in accordance with some embodiments. In some embodiments, during (and/or prior to) the second transfer stage, a wafer transport component 532 (e.g., a robot) transports the semiconductor wafer 102 to a position (e.g., the cleaning position) shown in FIG. 5B.

In some embodiments, during (and/or prior to) the second transfer stage, the set of roller caps undergo a second roller cap engagement process to enter a second roller cap engagement state. FIG. 5B depicts the set of roller caps in the second roller cap engagement state relative to the semiconductor wafer 102 in accordance with some embodiments. In some embodiments, when the set of roller caps are in the second roller cap engagement state, at least one of (i) the first roller cap 311 is in contact with and/or supports the semiconductor wafer 102, or (ii) the second roller cap 315 is in contact with and/or supports the semiconductor wafer 102. In some embodiments, the second roller cap engagement process comprises at least one of (i) movement of the first roller cap 311 in directions 534 and/or 536 (shown in FIG. 5B), or (ii) movement of the second roller cap 315 in directions 540 and/or 538 (shown in FIG. 5B).

In some embodiments, after the set of roller caps enter the second roller cap engagement state (shown in FIG. 5B), the semiconductor wafer 102 is moved in a direction 556 (shown in FIG. 5C) to separate the semiconductor wafer 102 from the wafer transport component 532. In some embodiments, the wafer transport component 532 leaves a cleaning environment of the cleaning apparatus 100 when the semiconductor wafer 102 is separated from the wafer transport component 532. In some embodiments, the set of roller caps is used to move the semiconductor wafer 102 in the direction 556, such as by the first roller cap 311 moving in a direction 552 and the second roller cap 315 moving in a direction 554.

FIG. 5D illustrates a side view of the cleaning apparatus 100 during a second cleaning stage of the cleaning process, in accordance with some embodiments.

In some embodiments, prior to (and/or during) the second cleaning stage, (i) the semiconductor wafer 102 is moved in a direction 522 to a target position shown in FIG. 5D (e.g., the cleaning position), (ii) a set of components comprising the first brush 104 (and/or the first roller 106) and the first fluid dispenser 202 moves in directions 514 and/or 516 (shown in FIG. 5D) to a target position shown in FIG. 5D. In some embodiments, the set of roller caps is used to move the semiconductor wafer 102 in the direction 522, such as by the first roller cap 311 moving in a direction 510 and the second roller cap 315 moving in a direction 512.

In some embodiments, during the second cleaning stage (and/or when the semiconductor wafer 102 and the set of components are in the respective target positions shown in FIG. 5D), at least one of (i) the first fluid dispenser 202 dispenses the third cleaning fluid (e.g., fluid 210) to the first brush 104 (ii) the first brush 104 is in contact with the first surface of the semiconductor wafer 102, (iii) at least some of the first cleaning fluid is transferred from the first brush 104 to the semiconductor wafer 102, (iv) the first brush 104 is rotated in a rotational direction 519, (v) the second fluid dispenser 204 dispenses the fourth cleaning fluid (e.g., fluid 212) to the second brush 108, (vi) the second brush 108 is in contact with the second surface of the semiconductor wafer 102, (vii) at least some of the second cleaning fluid is transferred from the second brush 108 to the semiconductor wafer 102, (viii) the second brush 108 is rotated in a rotational direction 521, or (ix) the semiconductor wafer 102 is rotated using the set of roller caps, such by the first roller cap 311 rotating in a rotational direction 518 while the first roller cap 311 is in contact with the semiconductor wafer 102 and/or the second roller cap 315 rotating in a rotational direction 520 while the second roller cap 315 is in contact with the semiconductor wafer 102.

In some embodiments, such as at least some of the implementations shown in and/or described with respect to FIGS. 1A-5D, the semiconductor wafer 102 is arranged horizontally during the cleaning process (e.g., the cleaning position corresponds to a horizontal arrangement of the semiconductor wafer 102). Embodiments are contemplated in which the semiconductor wafer 102 is arranged vertically (e.g., upright) or arranged at an angle during the cleaning process.

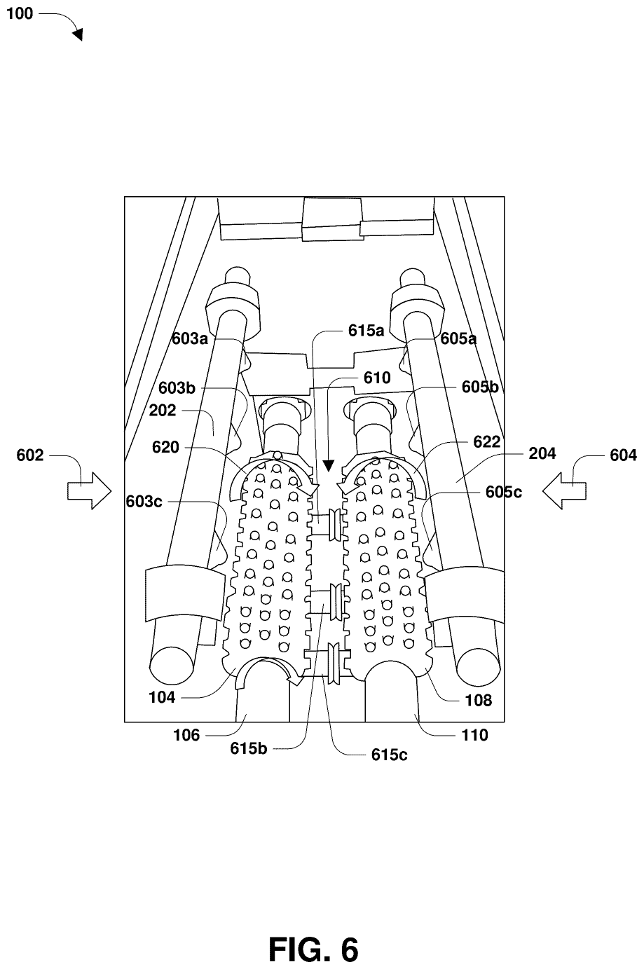

FIG. 6 illustrates the cleaning apparatus 100 according to some embodiments in which the semiconductor wafer 102 is arranged vertically during the cleaning process. In some embodiments, the set of roller caps comprises at least one of a roller cap 615a, a roller cap 615b, or a roller cap 615c. In some embodiments, the first fluid dispenser 202 is at a higher elevation than the first brush 104. In some embodiments, the third set of outlets comprises at least one of an outlet defined by a nozzle 603a, an outlet defined by a nozzle 603b, or an outlet defined by a nozzle 603c. In some embodiments, the second fluid dispenser 204 is at a higher elevation than the second brush 108. In some embodiments, the fourth set of outlets comprises at least one of an outlet defined by a nozzle 605a, an outlet defined by a nozzle 605b, or an outlet defined by a nozzle 605c.

In some embodiments, the semiconductor wafer 102 (not shown) is transferred (using a wafer transport component such as a robot, for example) into a space 610 between the first brush 104 and the second brush 108. In some embodiments, when the semiconductor wafer 102 is in the space 610 at least one of (i) the first brush 104 moves in a direction 602 towards the semiconductor wafer 102 or (ii) the second brush 108 moves in a direction 604 towards the semiconductor wafer 102. In some embodiments, during the cleaning process, at least one of (i) the semiconductor wafer 102 is supported in the cleaning position (e.g., an upright position of the semiconductor wafer 102) using at least one of the roller cap 615a, the roller cap 615b, or the roller cap 615c, (ii) the third cleaning fluid is dispensed by the third set of outlets of the first fluid dispenser 202 to at least one of the first brush 104 or the semiconductor wafer 102, (iii) the fourth cleaning fluid is dispensed by the fourth set of outlets of the second fluid dispenser 204 to at least one of the second brush 108 or the semiconductor wafer 102, (iv) the first brush 104 is in contact with the semiconductor wafer 102, (v) the first brush 104 is rotated in a rotational direction 620, (vi) the second brush 108 is in contact with the semiconductor wafer 102, (vii) the second brush 108 is rotated in a rotational direction 622, or (ix) the semiconductor wafer 102 is rotated using the set of roller caps, such by rotation of at least one of the roller cap 615a, the roller cap 615b, or the roller cap 615c.

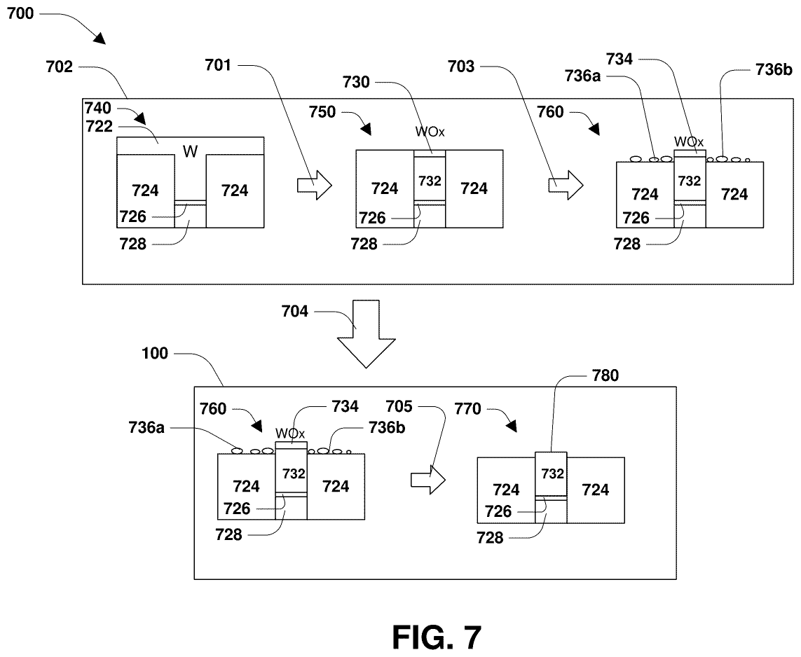

FIG. 7 illustrates a scenario 700 in accordance with some embodiments. In some embodiments, in the scenario 700, a first processing station 702 is used to prepare the semiconductor wafer 102, and the semiconductor wafer 102 is transferred 704 from the first processing station 702 to the cleaning apparatus 100.

In some embodiments, the first processing station 702 performs a first semiconductor fabrication process 701 on a first semiconductor wafer 740 to produce a first processed semiconductor wafer 750. In some embodiments, the first semiconductor fabrication process 701 comprises a first wafer polishing process, such as a first chemical mechanical planarization (CMP) process. Other types of fabrication processes of the first semiconductor fabrication process 701 are within the scope of the present disclosure.

In some embodiments, the first semiconductor wafer 740 comprises at least one of a dielectric layer 724, a first metal structure 728, a second metal structure 726, or a metal layer 722 over at least one of the dielectric layer 724, the first metal structure 728, or the second metal structure 726. In some embodiments, the dielectric layer 724 comprises an inter-metal dielectric (IMD) layer. In some embodiments, the dielectric layer 724 comprises at least one of an oxide semiconductor material, such as silicon dioxide, or other suitable material. In some embodiments, the first metal structure 728 comprises one or more metals. In some embodiments, the second metal structure 726 comprises at least one of titanium nitride or other suitable metal. In some embodiments, the metal layer 722 comprises at least one of tungsten or other suitable metal. In some embodiments, the first wafer polishing process comprises a tungsten chemical mechanical planarization (WCMP) process.

In some embodiments, the first wafer polishing process is performed to remove a top portion of the metal layer 722 to form a third metal structure 732 of the first processed semiconductor wafer 750. In some embodiments, the first wafer polishing process leaves metal oxide residue 730 on the first processed semiconductor wafer 750. In some embodiments, the metal oxide residue 730 (e.g., tungsten oxide residue) comprises metal oxide (e.g., tungsten oxide) that is formed during the first wafer polishing process, such as a result of one or more reactions between one or more materials used in the first wafer polishing process and the metal layer 722.

In some embodiments, the first processing station 702 (and/or a different processing station) performs a second semiconductor fabrication process 703 on the first processed semiconductor wafer 750 to produce a second processed semiconductor wafer 760. In some embodiments, the second semiconductor fabrication process 703 comprises a second wafer polishing process, such as a second chemical mechanical planarization (CMP) process. Other types of fabrication processes of the second semiconductor fabrication process 703 are within the scope of the present disclosure.

In some embodiments, the second wafer polishing process removes one or more top portions of the dielectric layer 724. In some embodiments, the second wafer polishing process leaves residue on the second processed semiconductor wafer 760. In some embodiments, the residue comprises at least one of metal oxide residue 734, slurry residue 736a, or slurry residue 736b. In some embodiments, the metal oxide residue 734 comprises the metal oxide residue 730 left from the first wafer polishing process.

In some embodiments, the semiconductor wafer 102 comprises the second processed semiconductor wafer 760. Other types, arrangements, etc. of the semiconductor wafer 102 are within the scope of the present disclosure. In some embodiments, the cleaning apparatus 100 is used to perform the cleaning process (shown with reference number 705) on the second processed semiconductor wafer 760 to remove at least some of the residue to produce a cleaned semiconductor wafer 770 without at least some of the residue. In some embodiments, the cleaning process 705 results in removal of at least some of the metal oxide residue 734, such as due, at least in part, to a reverse reaction between cleaning fluid (e.g., at least one of the first cleaning fluid, the second cleaning fluid, the third cleaning fluid, the fourth cleaning fluid, etc.) applied to the second processed semiconductor wafer 760 during the cleaning process 705 and the metal oxide residue 734. In some embodiments, the cleaning process 705 results in removal of at least some of the slurry residue 736a and/or 736b, such as due, at least in part, to the slurry residue 736a and/or 736b being scrubbed by one or more brushes and/or washed away by the cleaning fluid.

In some embodiments, the reverse reaction comprises a reduction-oxidation (redox) reaction. In some embodiments, the cleaning fluid comprises water (e.g., de-ionized water). In some embodiments, the reverse reaction comprises a reaction (e.g., a redox reaction) between water (e.g., de-ionized water) of the cleaning fluid and the metal oxide residue 734. In some embodiments, the reverse reaction comprises a reaction (e.g., a redox reaction) between water (e.g., de-ionized water) of the cleaning fluid and tungsten oxide of the metal oxide residue 734, such as according to the following equation: WO2+2H2O+2e⁻→W+4OH⁻.

In some embodiments, the cleaning fluid comprises hydrogen (e.g., H₂). In some embodiments, the reverse reaction comprises a reaction (e.g., a redox reaction) between hydrogen of the cleaning fluid and the metal oxide residue 734. In some embodiments, the reverse reaction comprises a reaction (e.g., a redox reaction) between hydrogen of the cleaning fluid and tungsten oxide of the metal oxide residue 734, such as according to the following equation:

$$WO 2 + 2 H 2 + 2 {e}^{-} \to W + 2 H 2 O .$$

In some embodiments, a temperature associated with the cleaning fluid is controlled using a fluid temperature controller (e.g., at least one of the first fluid temperature controller, the second fluid temperature controller, the third fluid temperature controller, or the fourth fluid temperature controller) to control a speed of the reverse reaction. In some embodiments, the temperature associated with the cleaning fluid is increased to increase a speed of the reverse reaction. In some embodiments, the cleaning apparatus 100 comprises the fluid temperature controller is configured to apply heat to a fluid (e.g., water and/or hydrogen) to produce a heated fluid, wherein the cleaning fluid applied to the second processed semiconductor wafer 760 comprises the heated fluid.

In some embodiments, the present disclosure provides for a cleaner semiconductor wafer 770 with a reduced amount of residue remaining on the cleaned semiconductor wafer 770. In some embodiments, performing the cleaning process 705 in accordance with the techniques provided herein results in a cleaner semiconductor wafer with a reduced amount of the metal oxide residue 734 (e.g., a reduced amount of tungsten oxide residue) remaining on the cleaned semiconductor wafer 770 in comparison with some cleaning processes that use cleaning fluid that does not comprise hydrogen and/or some cleaning processes that use cleaning fluid that is not temperature controlled and/or heated. In some embodiments, the reduced amount of the metal oxide residue 734, is due, at least in part, to (i) incorporating hydrogen in the cleaning process 705 (which may aid and/or improve the reverse reaction) and/or (ii) heating the cleaning fluid (which may aid and/or improve the reverse reaction). In some embodiments, the reduced amount of the metal oxide residue 734 provides for an improved electrical connection between the third metal structure 732 and a fourth metal structure (not shown) adjacent to and/or in contact with a surface 780 of the third metal structure 732. In some embodiments, the third metal structure 732 is an interconnect structure used to interconnect components in one or more layers of the cleaned semiconductor wafer 770. In some embodiments, the third metal structure 732 comprises at least one of a plug (e.g., a tungsten plug (W-plug)), a contact, a via, etc. In some embodiments, the improved electrical connection is associated with (i) improved electrical operation of a semiconductor device (e.g., a semiconductor device comprising the cleaned semiconductor wafer 770 and/or a semiconductor wafer produced from the cleaned semiconductor wafer 770), (ii) reduced electrical resistance between the third metal structure 732 and the fourth metal structure, or (iii) improved electrical conductivity and/or signal transfer between the third metal structure 732 and the fourth metal structure.

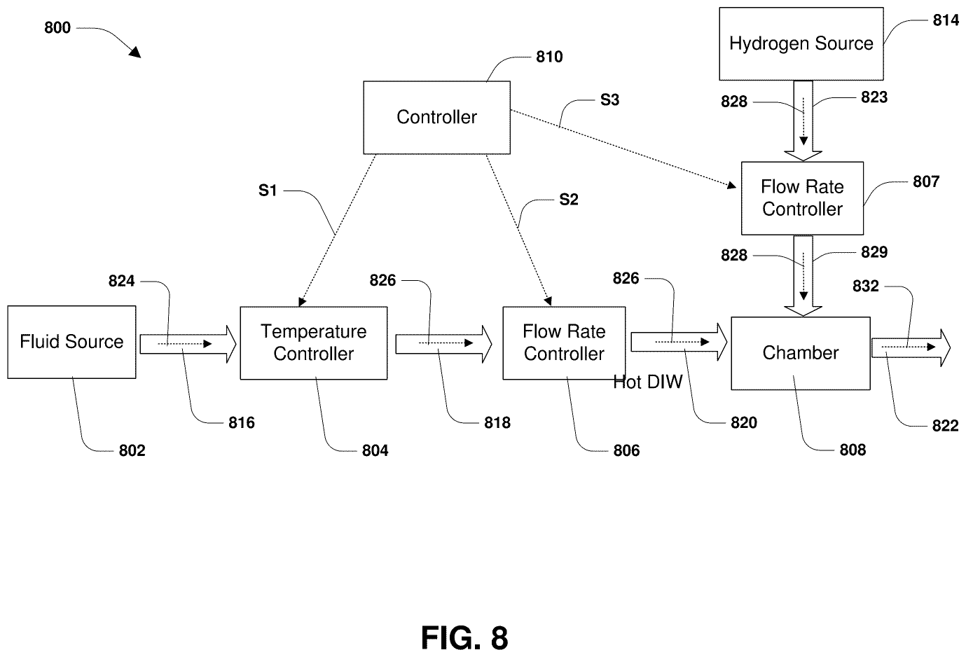

FIG. 8 illustrates a cleaning fluid system 800 configured to produce a cleaning fluid 832 (e.g., at least one of the first cleaning fluid, the second cleaning fluid, the third cleaning fluid, the fourth cleaning fluid, etc.) for application to the semiconductor wafer 102 (e.g., the second processed semiconductor wafer 760), in accordance with some embodiments. In some embodiments, the cleaning apparatus 100 comprises the cleaning fluid system 800. In some embodiments, the cleaning fluid system 800 comprises at least one of a fluid source 802 (e.g., a water source), a hydrogen source 814, a fluid temperature controller 804, a first flow control device 806, a second flow control device 807, a first chamber 808, or a controller 810.

In some embodiments, the cleaning fluid system 800 comprises one or more conduits 816 configured to conduct a fluid 824 from the fluid source 802 to the fluid temperature controller 804. In some embodiments, the fluid 824 comprises water (e.g., deionized water). In some embodiments, the fluid temperature controller 804 is configured to apply heat to the fluid 824 to produce a heated fluid 826 (e.g., heated deionized water). In some embodiments, the cleaning fluid system 800 comprises one or more conduits 818 configured to conduct the heated fluid 826 from the fluid temperature controller 804 to the first flow control device 806. In some embodiments, the first flow control device 806 comprises a mass flow controller. In some embodiments, the first flow control device 806 is configured to control a flow rate of the heated fluid 826, such as using one or more valves or one or more other suitable flow control components. In some embodiments, the cleaning fluid system 800 comprises one or more conduits 820 configured to conduct the heated fluid 826 from the first flow control device 806 to the first chamber 808. In some embodiments, the cleaning fluid system 800 comprises one or more conduits 823 configured to conduct hydrogen 828 from the hydrogen source 814 to the second flow control device 807. In some embodiments, the second flow control device 807 comprises a mass flow controller. In some embodiments, the second flow control device 807 is configured to control a flow rate of the hydrogen 828, such as using one or more valves or one or more other suitable flow control components. In some embodiments, the cleaning fluid system 800 comprises one or more conduits 829 configured to conduct the hydrogen 828 from the second flow control device 807 to the first chamber 808.

In some embodiments, the hydrogen 828 combines with the heated fluid 826 (e.g., heated deionized water) in the first chamber 808 to produce the cleaning fluid 832. In some embodiments, at least some of the hydrogen 828 dissolves in the heated fluid 826 to produce the cleaning fluid 832. In some embodiments, the cleaning fluid 832 comprises hydrogenated fluid (e.g., hydrogenated water). In some embodiments, at least some of the hydrogen 828 is infused with the heated fluid 826 to produce the cleaning fluid 832. In some embodiments, the cleaning fluid system 800 comprises one or more conduits 822 configured to conduct the cleaning fluid 832 to one or more inlets (e.g., at least one of the first roller inlet 153, the second roller inlet 155, the first dispenser inlet 253, or the second dispenser inlet 255) for use in the cleaning process.

In some embodiments, the controller 810 is configured to determine a recipe associated with the cleaning process. In some embodiments, the recipe is indicative of at least one of a target temperature of the cleaning fluid 832 for use in the cleaning process, a first target flow rate of the heated fluid 826 (and/or the fluid 824) and/or a second target flow rate of the hydrogen 828.

In some embodiments, the controller 810 determines at least one of the recipe, the target temperature, the first target flow rate, or the second target flow rate based upon at least one of (i) a pattern density of the semiconductor wafer 102, (ii) a measure of tungsten of the semiconductor wafer 102, or (iii) a measure of tungsten oxide of the semiconductor wafer 102. In some embodiments, the pattern density corresponds to a density of metal structures on a surface of the semiconductor wafer 102. In some embodiments, the measure of tungsten corresponds to a measure (e.g., a density and/or concentration) of tungsten on a surface of the semiconductor wafer 102 (e.g., a measure of tungsten on at least one of the first semiconductor wafer 740, the first processed semiconductor wafer 750, or the second processed semiconductor wafer 760). In some embodiments, the measure of tungsten oxide corresponds to a measure (e.g., a density) of tungsten oxide on a surface of the semiconductor wafer 102 (e.g., a measure of tungsten oxide on at least one of the first processed semiconductor wafer 750 or the second processed semiconductor wafer 760). In some embodiments, the controller 810 determines the target temperature as a function of at least one of the pattern density, the measure of tungsten, or the measure of tungsten oxide, such as where an increase of at least one of the pattern density, the measure of tungsten, or the measure of tungsten oxide is associated with an increase of the target temperature. In some embodiments, the controller 810 determines the first target flow rate as a function of at least one of the pattern density, the measure of tungsten, or the measure of tungsten oxide, such as where an increase of at least one of the pattern density, the measure of tungsten, or the measure of tungsten oxide is associated with an increase of the first target flow rate. In some embodiments, the controller 810 determines the second target flow rate as a function of at least one of the pattern density, the measure of tungsten, or the measure of tungsten oxide, such as where an increase of at least one of the pattern density, the measure of tungsten, or the measure of tungsten oxide is associated with an increase of the second target flow rate.

In some embodiments, the controller 810 transmits a control signal S1 to the fluid temperature controller 804. In some embodiments, the control signal S1 is indicative of at least one of the recipe or the target temperature. In some embodiments, the fluid temperature controller 804 controls a temperature of the heated fluid 826 based upon the target temperature. In some embodiments, the controller 810 transmits a control signal S2 to the first flow control device 806. In some embodiments, the control signal S2 is indicative of at least one of the recipe or the first target flow rate. In some embodiments, the first flow control device 806 controls a flow rate of the heated fluid 826 (and/or the fluid 824) based upon the first target flow rate. In some embodiments, the controller 810 transmits a control signal S3 to the second flow control device 807. In some embodiments, the control signal S3 is indicative of at least one of the recipe or the second target flow rate. In some embodiments, the second flow control device 807 controls a flow rate of the hydrogen 828 based upon the second target flow rate.

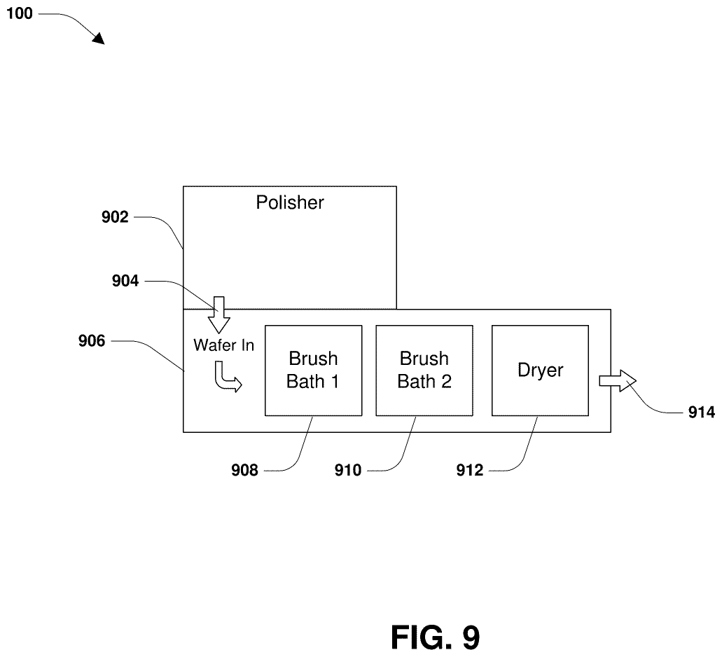

FIG. 9 illustrates the cleaning apparatus 100 in accordance with some embodiments. In some embodiments, the cleaning apparatus 100 comprises (i) a processing station 902 (e.g., a polisher) configured to perform one or more semiconductor fabrication processes (e.g., the first semiconductor fabrication process 701 and/or the second semiconductor fabrication process 703) that leaves residue (e.g., tungsten oxide residue) on the semiconductor wafer 102, (ii) a wafer transfer component (not shown) configured to transfer the semiconductor wafer 102 with the residue to a cleaning station 906, (iii) the cleaning station 906 (e.g., a post-CMP cleaning station). In some embodiments, the cleaning station 906 comprises at least one of a first brush bath 908 configured to perform the cleaning process on the semiconductor wafer 102 (using the cleaning fluid 832, for example), a second brush bath 910 configured to perform a second cleaning process on the semiconductor wafer 102 (using the cleaning fluid 832 or a different cleaning fluid, for example) subsequent to the cleaning process, or a dryer 912 configured to perform a drying process on the semiconductor wafer 102 after the second cleaning process. In some embodiments, subsequent to the drying process, the semiconductor wafer 102 is transferred 914 from the cleaning apparatus 100 to outside the cleaning apparatus 100.

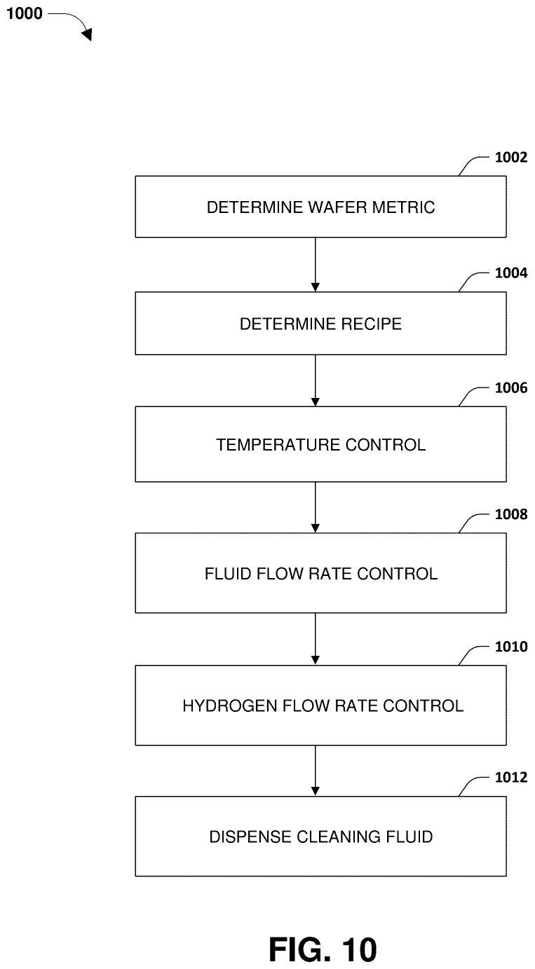

FIG. 10 illustrates a method 1000 of performing the cleaning process on the semiconductor wafer 102, in accordance with some embodiments. At 1002, the controller 810 determines a wafer metric associated with the semiconductor wafer 102. In some embodiments, the wafer metric is indicative of at least one of the pattern density of the semiconductor wafer 102, the measure of tungsten of the semiconductor wafer 102, or the measure of tungsten oxide of the semiconductor wafer 102. At 1004, the controller 810 determines the recipe based upon the wafer metric. In an example, the controller 810 selects the recipe from a plurality of recipes associated with different values of the wafer metric.

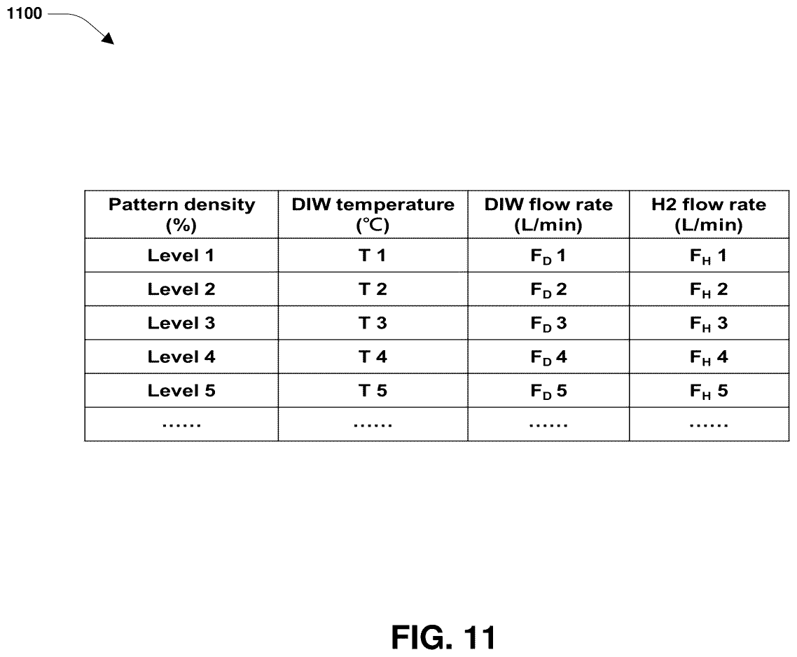

In some embodiments, the controller 810 determines at least one of the recipe, the target temperature, the first target flow rate, or the second target flow rate using a wafer metric data structure. FIG. 11 illustrates a representation 1100 of the wafer metric data structure, in accordance with some embodiments. In some embodiments, the wafer metric data structure is indicative of a plurality of wafer metric values (e.g., Level 1, Level 2, Level 3, etc.). In some embodiments, for each wafer metric value of the plurality of wafer metric values, the wafer metric data structure comprises at least one of (i) a corresponding target temperature (e.g., T1, T2, T3, etc.), (ii) a corresponding first target flow rate (e.g., F_{D}1, F_{D}2, F_{D}3, etc.), or (iii) a corresponding second target flow rate (e.g., F_{H}1, F_{H}2, F_{H}3, etc.). In a scenario in which the wafer metric associated with the semiconductor wafer 102 corresponds to Level 2, at least one of (i) the target temperature is set to T2, (ii) the first target flow rate is set to F_{D}2, or (iii) the second target flow rate is set to F_{H}2. In some embodiments, each target temperature of one, some or all target temperatures of the wafer metric data structure (e.g., T1, T2, T3, etc.) is between about 25 degrees Celsius to about 90 degrees Celsius. In some embodiments, each first target flow rate of one, some or all first target flow rates of the wafer metric data structure (e.g., F_{D}1, F_{D}2, F_{D}3, etc.) is between about 0.5 liters per minute to about 80 liters per minute. In some embodiments, each second target flow rate of one, some or all second target flow rates of the wafer metric data structure (e.g., F_{H}1, F_{H}2, F_{H}3, etc.) is between about 0.5 liters per minute to about 100 liters per minute.

At 1006, the controller 810 transmits an indication of the target temperature to the fluid temperature controller 804 and/or the fluid temperature controller 804 applies heat to the fluid 824 based upon the target temperature. At 1008, the controller 810 transmits an indication of the first target flow rate to the first flow control device 806 and/or the first flow control device 806 controls a flow rate of the heated fluid 826 (and/or the fluid 824) based upon the first target flow rate. At 1010, the controller 810 transmits an indication of the second target flow rate to the second flow control device 807 and/or the second flow control device 807 controls a flow rate of the hydrogen 828 based upon the second target flow rate. At 1012, the cleaning fluid 832 (produced based upon the target temperature, the first target flow rate and/or the second target flow rate) is dispensed to at least one of the semiconductor wafer 102 or one or more brushes of the set of brushes to perform the cleaning process.

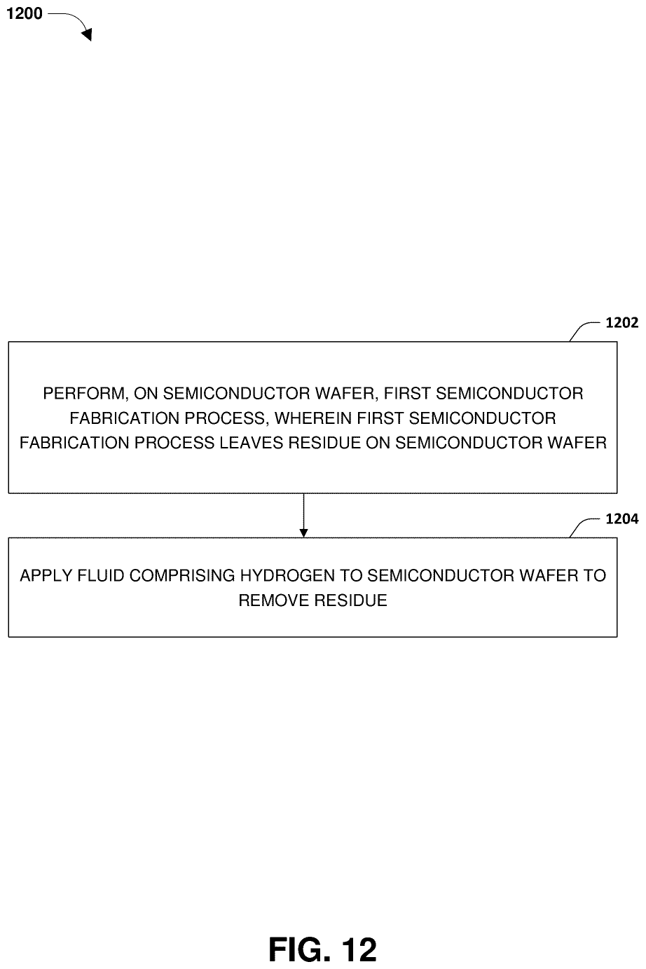

A method 1200 is illustrated in FIG. 12 in accordance with some embodiments. The method 1200 includes performing, at 1202, a first semiconductor fabrication process (e.g., the first semiconductor fabrication process 701 and/or the second semiconductor fabrication process 703) on a semiconductor wafer (e.g., the semiconductor wafer 102). The first semiconductor fabrication process leaves residue (e.g., metal oxide residue 734) on the semiconductor wafer. The method 1200 includes applying, at 1204, a fluid (e.g., the cleaning fluid 832) comprising hydrogen to the semiconductor wafer to remove the residue.

In some embodiments, each conduit of one, some, or all conduits of the present disclosure at least one of (i) is used for transferring fluids or (ii) comprises at least one of one or more tubes, one or more pipes, one or more fluid transport lines, one or more fluid transport hoses, one or more manifolds, etc.

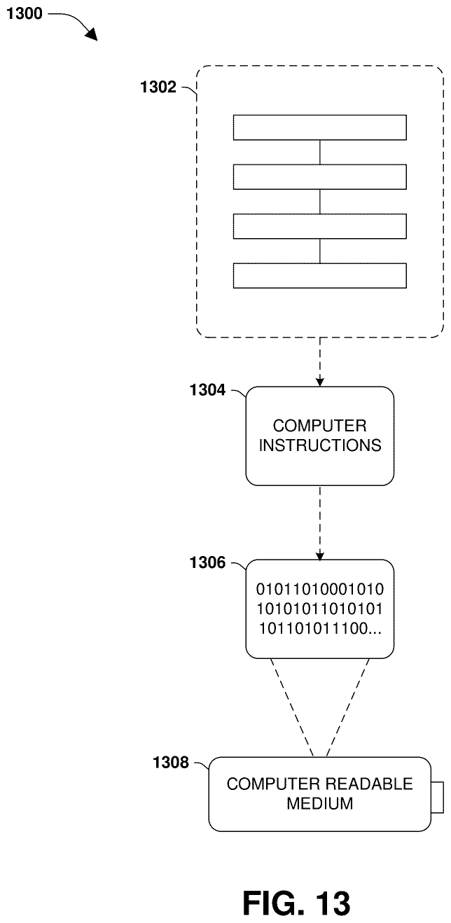

One or more embodiments involve a computer-readable medium comprising processor-executable instructions configured to implement one or more of the techniques presented herein. An exemplary computer-readable medium is illustrated in FIG. 13, wherein the embodiment 1300 comprises a computer-readable medium 1308 (e.g., a CD-R, DVD-R, flash drive, a platter of a hard disk drive, etc.), on which is encoded computer-readable data 1306. This computer-readable data 1306 in turn comprises a set of processor-executable computer instructions 1304 configured to implement one or more of the principles set forth herein when executed by a processor. In some embodiments 1300, the processor-executable computer instructions 1304 are configured to implement a method 1302, such as at least some of the aforementioned method(s) when executed by a processor. In some embodiments, the processor-executable computer instructions 1304 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, an apparatus is provided. The apparatus includes a wafer support assembly configured to support a semiconductor wafer in a cleaning position. The apparatus includes a wafer cleaning assembly configured to apply a fluid including hydrogen to the semiconductor wafer while the semiconductor wafer is in the cleaning position.

In some embodiments, a method is provided. The method includes performing, on a semiconductor wafer, a first semiconductor fabrication process. The first semiconductor fabrication process leaves residue on the semiconductor wafer. A fluid including hydrogen is applied to the semiconductor wafer to remove the residue.

In some embodiments, an apparatus is provided. The apparatus includes a wafer cleaning assembly configured to apply a fluid including hydrogen to a semiconductor wafer having tungsten oxide residue.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. An apparatus, comprising:
a wafer support assembly configured to support a semiconductor wafer in a cleaning position; and
a wafer cleaning assembly configured to apply a fluid comprising hydrogen to the semiconductor wafer while the semiconductor wafer is in the cleaning position.

2. The apparatus of claim 1, wherein:
application of the fluid to the semiconductor wafer causes a reverse reaction of tungsten oxide residue on a surface of the semiconductor wafer.

3. The apparatus of claim 1, wherein the wafer cleaning assembly comprises:
a brush configured to be in contact with the semiconductor wafer while the semiconductor wafer is in the cleaning position.

4. The apparatus of claim 3, wherein the wafer cleaning assembly comprises:
a roller configured to rotate the brush while the semiconductor wafer is in the cleaning position.

5. The apparatus of claim 3, wherein the wafer cleaning assembly comprises:
one or more outlets configured to emit the fluid to the brush while the semiconductor wafer is in the cleaning position.

6. The apparatus of claim 3, wherein the wafer cleaning assembly comprises:
one or more outlets configured to emit the fluid to the semiconductor wafer while the semiconductor wafer is in the cleaning position.

7. The apparatus of claim 1, comprising:
a fluid temperature controller configured to apply heat to a second fluid to produce a heated fluid, wherein the fluid applied to the semiconductor wafer comprises the heated fluid.

8. The apparatus of claim 7, wherein:
application of the fluid to the semiconductor wafer causes a reverse reaction of tungsten oxide residue on a surface of the semiconductor wafer; and
a speed of the reverse reaction increases based upon an increase of a temperature associated with the heated fluid.

9. The apparatus of claim 7, wherein:
the fluid temperature controller is configured to control a temperature associated with the heated fluid based upon at least one of:
a pattern density of the semiconductor wafer;
a measure of tungsten of the semiconductor wafer; or
a measure of tungsten oxide of the semiconductor wafer.

10. The apparatus of claim 1, comprising:
a flow control device configured to control a flow rate of the fluid based upon at least one of:
a pattern density of the semiconductor wafer;
a measure of tungsten of the semiconductor wafer; or
a measure of tungsten oxide of the semiconductor wafer.

11. The apparatus of claim 1, wherein:
the fluid comprises water.

12. The apparatus of claim 11, comprising:
a flow control device configured to control a flow rate of the water based upon at least one of:
a pattern density of the semiconductor wafer;
a measure of tungsten of the semiconductor wafer; or
a measure of tungsten oxide of the semiconductor wafer.

13. The apparatus of claim 11, comprising:
one or more first conduits configured to conduct the water to a first chamber;
one or more second conduits configured to conduct the hydrogen to the first chamber; and
one or more third conduits configured to conduct the fluid comprising the water and the hydrogen from the first chamber to one or more outlets configured to emit the fluid.

14. The apparatus of claim 1, wherein:
the wafer support assembly comprises one or more roller caps configured to rotate the semiconductor wafer while the semiconductor wafer is in the cleaning position.

15. A method, comprising:
performing, on a semiconductor wafer, a first semiconductor fabrication process, wherein the first semiconductor fabrication process leaves residue on the semiconductor wafer; and
applying a fluid comprising hydrogen to the semiconductor wafer to remove the residue.

16. The method of claim 15, wherein:
the residue comprises tungsten oxide; and
application of the fluid to the semiconductor wafer causes a reverse reaction of the tungsten oxide.

17. The method of claim 15, comprising:
applying heat to a second fluid to produce a heated fluid, wherein the fluid applied to the semiconductor wafer comprises the heated fluid.

18. The method of claim 17, comprising:
controlling a temperature associated with the heated fluid based upon at least one of:
a pattern density of the semiconductor wafer;
a measure of tungsten of the semiconductor wafer; or
a measure of tungsten oxide comprised within the residue on the semiconductor wafer.

19. An apparatus, comprising:
a wafer cleaning assembly configured to apply a fluid comprising hydrogen to a semiconductor wafer having tungsten oxide residue.

20. The apparatus of claim 19, comprising:
a fluid temperature controller configured to apply heat to a second fluid to produce a heated fluid, wherein the fluid applied to the semiconductor wafer comprises the heated fluid.
